(19) United States
(12) Patent Application Publication
(10) Pub. No.: US 2021/0366710 A1
(43) Pub. Date: Nov. 25, 2021

(54) METHOD FOR MANUFACTURING SEMICONDUCTOR CRYSTALLINE THIN FILM AND LASER ANNEALING SYSTEM

(71) Applicants: Gigaphoton Inc., Tochigi (JP); KYUSHU UNIVERSITY, NATIONAL UNIVERSITY CORPORATION, Fukuoka (JP)

(72) Inventors: Kaname IMOKAWA, Oyama-shi (JP); Ryoichi NOHDOMI, Oyama-shi (JP); Osamu WAKABAYASHI, Oyama-shi (JP); Hiroshi IKENOUE, Fukuoka-shi (JP)

(73) Assignees: Gigaphoton Inc., Tochigi (JP); KYUSHU UNIVERSITY, NATIONAL UNIVERSITY CORPORATION, Fukuoka (JP)

(21) Appl. No.: 17/392,926

(22) Filed: Aug. 3, 2021

Related U.S. Application Data
(63) Continuation of application No. PCT/JP2019/009078, filed on Mar. 7, 2019.

(51) Int. Cl. H01L 21/02; H01S 3/00; H01S 3/11; H01S 3/23; H01L 21/67

(52) U.S. Cl. CPC H01L 21/02686; H01S 3/0057; H01S 3/11; H01S 3/2366; H01S 3/225; H01L 21/02592; H01L 21/02678; H01L 21/67115; H01L 21/02532

(57) ABSTRACT

A method for manufacturing a semiconductor crystalline thin film according to a viewpoint of the present disclosure includes radiating first pulsed laser light having a first pulse duration to an amorphous semiconductor to poly-crystallize the amorphous semiconductor and radiating second pulsed laser light having a second pulse duration shorter than the first pulse duration to an area of a semiconductor crystal having undergone the poly-crystallization to lower the height of ridges of the semiconductor crystal.

### CROSS-REFERENCE TO RELATED APPLICATIONS

The present application is a continuation application of International Application No. PCT/JP2019/009078, filed on Mar. 7, 2019, the entire contents of which are hereby incorporated by reference.

### BACKGROUND

### 1. Technical Field

The present disclosure relates to a method for manufacturing a semiconductor crystalline thin film and a laser annealing system.

### 2. Related Art

A thin film transistor (TFT) is used as a driver of a flat panel display using a glass substrate. To achieve a high-definition display, it is necessary to produce a high driving power TFT. A semiconductor thin film that forms the channel of a TFT is made of polycrystalline silicon or indium gallium zinc oxide (IGZO). Polycrystalline silicon and IGZO have higher carrier mobility and more excellent transistor on/off characteristics than amorphous silicon.

Semiconductor thin films are also expected to be used in 3D ICs that achieve devices having more advanced functions. A 3D IC is achieved by forming active elements, such as a sensor, an amplification circuit, and a CMOS circuit, in the top layer of an integrated circuit device. To this end, a technology for manufacturing higher quality semiconductor thin films is required.

Further, diversification of information terminal instruments is creating a growing demand for flexible displays and computers that are compact and lightweight, consume less power, and can be freely folded. It is therefore required to establish a technology for forming a high-quality semiconductor thin film on a plastic substrate made, for example, of PET (polyethylene terephthalate).

To form a high-quality semiconductor thin film on a glass substrate, an integrated circuit, or a plastic substrate, it is necessary to crystallize the semiconductor thin film without thermal damage to the substrate. A process temperature of 400° C. is required for glass substrates used to form displays, 400° C. for integrated circuits, and 200° C. or lower for PET used to form plastic substrates.

Laser annealing is used as a technology for crystallizing a semiconductor thin film without thermal damage to the substrate under the semiconductor thin film. In the laser annealing, pulsed ultraviolet laser light absorbed by an upper-layer semiconductor thin film is used to suppress damage to the substrate due to thermal diffusion.

When the semiconductor thin film is made of silicon, an XeF excimer laser, which emits light having a wavelength of 351 nm, an XeCl excimer laser, which emits light having a wavelength of 308 nm, a KrF excimer laser, which emits light having a wavelength of 248 nm, or any other suitable laser is used. The ultraviolet gas lasers described above are characterized in that they emit laser light having lower laser light interference, provide excellent energy uniformity at the laser light irradiated surface, and allow uniform annealing of a large area with high pulse energy, as compared with solid-state lasers.

### CITATION LIST

### Patent Literature

[PTL 1] US Patent Application Publication No. 2005/0211987
[PTL 2] JP-A-2007-287866
[PTL 3] U.S. Pat. No. 6,117,752
[PTL 4] US Patent Application Publication No. 2018/0040718
[PTL 5] WO 2018/047220

### SUMMARY

A method for manufacturing a semiconductor crystalline thin film according to a viewpoint of the present disclosure includes radiating first pulsed laser light having a first pulse duration to an amorphous semiconductor to poly-crystallize the amorphous semiconductor and radiating second pulsed laser light having a second pulse duration shorter than the first pulse duration to an area of a semiconductor crystal having undergone the poly-crystallization due to the radiation of the first pulsed laser light to lower a height of ridges of the semiconductor crystal.

A laser annealing system according to another viewpoint of the present disclosure includes a laser system configured to output first pulsed laser light having a first pulse duration and second pulsed laser light having a second pulse duration shorter than the first pulse duration and a laser annealing apparatus configured to radiate the first pulsed laser light and the second pulsed laser light to a radiation receiving object, and the laser annealing apparatus including a radiation optical system configured to guide the first pulsed laser light and the second pulsed laser light to the radiation receiving object, a movement mechanism configured to move relative to the radiation receiving object radiation positions to which the first pulsed laser light and the second pulsed laser light are radiated, and a controller configured to control the laser system in such a way that the first pulsed laser light is radiated to the radiation receiving object and after the first pulsed laser light is radiated, the second pulsed laser light is radiated to an area of the radiation receiving object that is an area to which the first pulsed laser light is radiated.

### BRIEF DESCRIPTION OF THE DRAWINGS

Embodiments of the present disclosure will be described below only by way of example with reference to the accompanying drawings.

FIG. 1 describes a pulse duration of laser light.

FIG. 2 schematically shows the configuration of an exemplary laser annealing system.

FIG. 3 is a plan view showing an example of the relationship between a pattern on a mask and a linear beam with which the mask is illuminated.

FIG. 4 is a plan view showing an example of linear beam scan radiation performed on a radiation receiving object.

FIG. 5 is an enlarged view of the portion surrounded by the broken circle in FIG. 4.

FIG. 6 is a flowchart showing an example of the operation of the laser annealing system.

FIG. 7 is a flowchart showing an example of the subroutine applied to step S12 in FIG. 6.

FIG. 8 is a flowchart showing an example of the subroutine applied to step S14 in FIG. 6.

FIG. 9 is a flowchart showing an example of the subroutine applied to step S20 in FIG. 6.

FIG. 10 is a flowchart showing an example of the subroutine applied to step S22 in FIG. 6.

FIG. 11 is a diagrammatic view of the process of manufacturing a semiconductor crystalline thin film based on laser annealing.

FIG. 12 is a diagrammatic view showing an example of the process of manufacturing a semiconductor crystalline thin film according to a first embodiment.

FIG. 13 is a table showing laser light radiation conditions applied to a test.

FIG. 14 shows graphs illustrating examples of the pulse waveform of the laser light.

FIG. 15 shows an example of the configuration of an optical pulse stretcher system.

FIG. 16 shows examples of the mask pattern and crystal growth.

FIG. 17 schematically shows the configuration of a laser annealing system according to the first embodiment.

FIG. 18 is a plan view showing an example of beam scan radiation at the time of ridge planarization in the first embodiment.

FIG. 19 is a flowchart showing an example of the operation of the laser annealing system according to the first embodiment.

FIG. 20 is a flowchart showing an example of the subroutine applied to step S13 in FIG. 19.

FIG. 21 is a flowchart showing an example of the subroutine applied to step S21 in FIG. 19.

FIG. 22 is a flowchart showing an example of the subroutine applied to step S24 in FIG. 19.

FIG. 23 is a flowchart showing an example of the subroutine applied to step S26 in FIG. 19.

FIG. 24 is a flowchart showing an example of the subroutine applied to step S28 in FIG. 19.

FIG. 25 schematically shows the configuration of a laser annealing system according to a second embodiment.

FIG. 26 schematically shows the configuration of a laser annealing system according to a third embodiment.

FIG. 27 is a plan view showing an example of the relationship between the pattern on the mask and linear beams with which the mask is illuminated.

FIG. 28 is a plan view showing an example of the linear beam scan radiation performed on the radiation receiving object.

FIG. 29 schematically shows the configuration of a laser annealing system according to a fourth embodiment.

FIG. 30 schematically shows the configuration of a laser annealing system according to a fifth embodiment.

FIG. 31 schematically shows the configuration of a laser annealing system according to a sixth embodiment.

FIG. 32 shows an example of a mask and a beam irradiated area of the mask.

FIG. 33 is an enlarged view showing an example of a fine pattern formed in each pattern area of the mask.

FIG. 34 describes the operation of the laser annealing system according to the sixth embodiment.

FIG. 35 schematically shows the configuration of a laser annealing system according to a seventh embodiment.

FIG. 36 schematically shows the configuration of a laser annealing system according to an eighth embodiment.

### DETAILED DESCRIPTION

### Contents

1. Description of terms
2. Overall description of laser annealing system

2.1 Configuration

2.2 Operation

2.3 Example of operation

2.4 Others

### 3. Problems

### 4. First Embodiment

4.1 Overview of method for manufacturing semiconductor crystalline thin film

4.2 Example of radiation conditions

4.3 Examples of mask pattern and crystal growth

4.4 Configuration of laser annealing system

4.5 Operation

4.6 Example of operation

4.7 Effects and advantages

4.8 Variations

### 5. Second Embodiment

5.1 Configuration

5.2 Operation

5.3 Effects and advantages

### 6. Third Embodiment

6.1 Configuration

6.2 Operation

6.3 Effects and advantages

### 7. Fourth Embodiment

7.1 Configuration

7.2 Operation

7.3 Effects and advantages

7.4 Variations

### 8. Fifth Embodiment

8.1 Configuration

8.2 Operation

8.3 Effects and advantages

8.4 Variations

### 9. Sixth Embodiment

9.1 Configuration

9.2 Operation

9.3 Effects and advantages

9.4 Variations

### 10. Seventh Embodiment

10.1 Configuration

10.2 Operation

10.3 Effects and advantages

10.4 Variations

### 11. Eighth Embodiment

11.1 Configuration

11.2 Operation

11.3 Effects and advantages

11.4 Variations

### 12. Others

Embodiments of the present disclosure will be described below in detail with reference to the drawings. The embodiments described below show some examples of the present disclosure and are not intended to limit the contents of the present disclosure. Further, all configurations and operations described in the embodiments are not necessarily essential as configurations and operations in the present disclosure. The same component has the same reference character, and no redundant description of the same component will be made.

### 1. Description of Terms

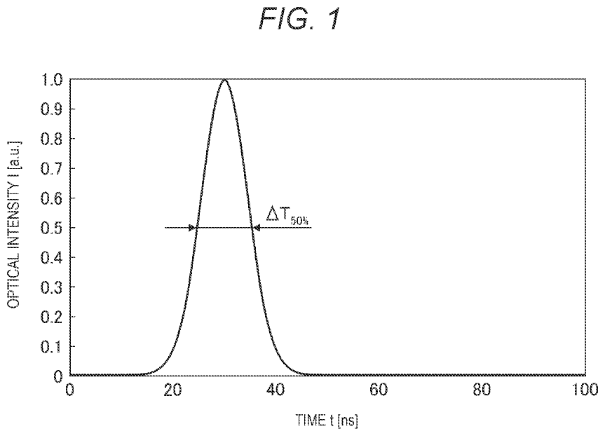

FIG. 1 describes a pulse duration of laser light. The vertical axis of FIG. 1 represents optical intensity I [a. u.], and the horizontal axis of FIG. 1 represents time t [ns]. The optical intensity I [a. u.] is a normalized value, that is, the optical intensity I divided by a peak value of the waveform of the optical intensity (maximum optical intensity value). A pulse duration ΔT_{50%} can be used as one of the indicators of the pulse duration of the laser light. The pulse duration ΔT_{50%} refers to the overall duration at 50% of the maximum optical intensity value, as shown in FIG. 1.

A TIS pulse duration ΔT_{TIS} can also be used as another indicator of the pulse duration of the laser light.

The TIS pulse duration ΔT_{TIS} is defined by Expression (1) below.

$$\begin{matrix}[ Numerical expression 1 ] & \\ Δ {T}_{TIS} = \frac{{[ \int I ( t ) dt ]}^{2}}{\int {I ( t )}^{2} dt} & ( 1 )\end{matrix}$$

In Expression (1), t represents time, and I(t) represents the optical intensity at time t.

### 2. Overall Description of Laser Annealing System

2.1 Configuration

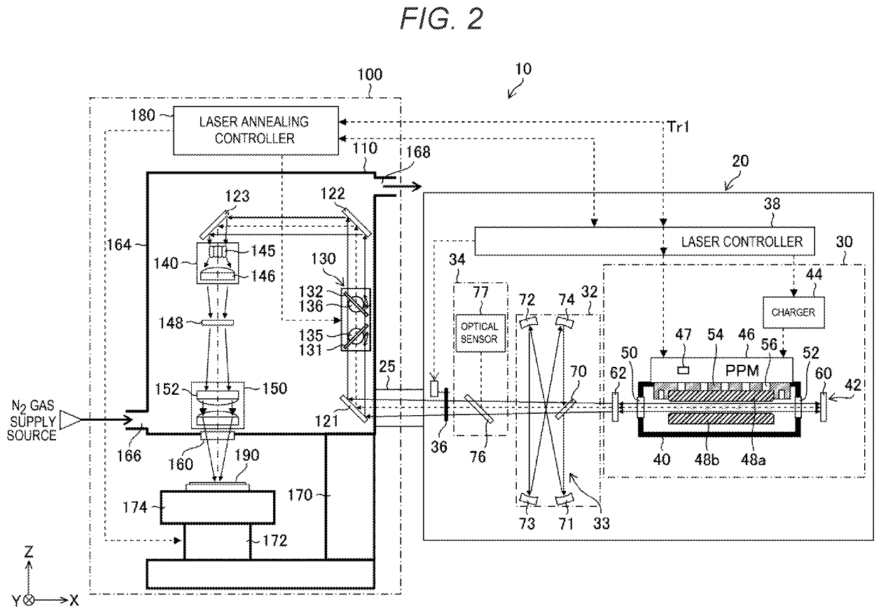

FIG. 2 schematically shows the configuration of an exemplary laser annealing system. A laser annealing system 10 includes a laser apparatus 20, an optical path tube 25, and a laser annealing apparatus 100. The optical path tube 25 is disposed in an optical path of the laser light between a laser light exiting port of the laser apparatus 20 and a laser light incident port of the laser annealing apparatus 100.

The laser apparatus 20 is a laser apparatus configured to output ultraviolet pulsed laser light. For example, the laser apparatus 20 may be a discharge-excitation-type laser apparatus using a laser medium made of F₂, ArF XeCl, or XeF. The laser apparatus 20 includes a master oscillator (MO) 30, an optical pulse stretcher (OPS) system 32, a monitoring module 34, a shutter 36, and a laser controller 38.

The master oscillator 30 includes a chamber 40, an optical resonator 42, a charger 44, and a pulse power module (PPM) 46.

The chamber 40 encapsulates an excimer laser gas containing the laser medium. The excimer laser gas may be a mixed gas containing a rare gas, such as Ar, Kr, or Xe, a halogen gas, such as F₂ or Cl₂, and a buffer gas, such as He or Ne.

The chamber 40 includes a pair of electrodes 48a and 48b and windows 50 and 52. The pair of electrodes 48a and 48b are disposed in the chamber 40. The electrode 48a is supported by an insulating member 54. The electrode 48a is connected to the PPM 46 via conductive sections 56 embedded in feedthrough sections of the insulating member 54. The electrode 48b is supported by a return plate that is not shown, and the return plate is connected to the inner surface of the chamber 40 via wiring that is not shown.

The PPM 46 includes a switch 47, a step-up transformer, and a magnetic compression circuit, neither of the latter two components is shown. The PPM 46 is connected to the charger 44. The charger 44 is a DC power supply apparatus configured to charge a charging capacitor that is not shown in the PPM 46 with predetermined voltage.

The optical resonator 42 includes a rear mirror 60 and an output coupling mirror 62. The rear mirror 60 is formed of a planar substrate coated with a high-reflectance film. The output coupling mirror 62 is formed of a planar substrate coated with a partially reflective film. The chamber 40 is disposed in an optical path of the optical resonator 42.

The OPS system 32 is disposed in an optical path between the master oscillator 30 and the monitoring module 34. The OPS system 32 includes an optical pulse stretcher (OPS) 33 configured to delay part of the light incident thereon to stretch the duration of the pulsed laser light.

The OPS 33 includes a beam splitter 70 and concave mirrors 71 to 74. The beam splitter 70 is disposed in the optical path between the master oscillator 30 and the monitoring module 34. The beam splitter 70 is coated with a film configured to partially reflect part of the pulsed laser light incident thereon.

The concave mirrors 71 to 74 have the same focal length and are so disposed that the pulsed laser light beam reflected off the beam splitter 70 is reflected off the four concave mirrors 71 to 74 at high reflectance and transferred to the position where the pulsed laser light is incident on the beam splitter 70 again.

The monitoring module 34 includes a beam splitter 76 and an optical sensor 77.

The shutter 36 is disposed in an optical path of the pulsed laser light outputted from the monitoring module 34.

The optical path of the pulsed laser light may be encapsulated by an enclosure that is not shown and the optical path tube 25 and purged, for example, with an N₂ gas.

The laser annealing apparatus 100 includes a radiation optical system 110, a frame 170, an XYZ-axis stage 172, a table 174, and a laser annealing controller 180. A radiation receiving object 190 is fixed onto the table 174.

The radiation optical system 110 includes high-reflectance mirrors 121 to 123, an attenuator 130, an illumination optical system 140, a mask 148, a projection optical system 150, a window 160, and an enclosure 164.

The high-reflectance mirror 121 is so disposed that the laser light having passed through the optical path tube 25 passes through the attenuator 130 and is incident on the high-reflectance mirror 122.

The attenuator 130 is disposed in an optical path between the high-reflectance mirror 121 and the high-reflectance mirror 122. The attenuator 130 includes two partially reflective mirrors 131 and 132 and rotary stages 135 and 136 capable of changing the angles of incidence of the light incident on the partially reflective mirrors 131 and 132.

The high-reflectance mirror 122 is so disposed that the laser light having passed through the attenuator 130 is incident on the high-reflectance mirror 123. The high-reflectance mirror 123 is so disposed that the pulsed laser light incident thereon enters a fly-eye lens 145 of the illumination optical system 140.

The illumination optical system 140 includes the fly-eye lens 145 and a condenser lens 146. The illumination optical system 140 is an optical system for uniform illumination of a predetermined illumination receiving area on the mask 148 and is so disposed that the mask 148 is illuminated in the form of Koehler illumination with a rectangular beam. Let Bmx be the X-axis-direction beam width of the rectangular beam radiated onto the mask 148 and Bmy be the Y-axis-direction beam width of the rectangular beam. The rectangular beam is assumed in the description to have a rectangular shape that satisfies Bmx<Bmy, that is, a rectangular shape having a longitudinal direction coincides with the Y-axis direction. The rectangular beam is called a “linear beam” in the present specification.

The fly-eye lens 145 is so disposed, for example, that the focal plane of the fly-eye lens 145 coincides with the front focal plane of the condenser lens 146, and the condenser lens 146 is so disposed, for example, that the rear focal plane of the condenser lens 146 coincides with the position of the mask 148.

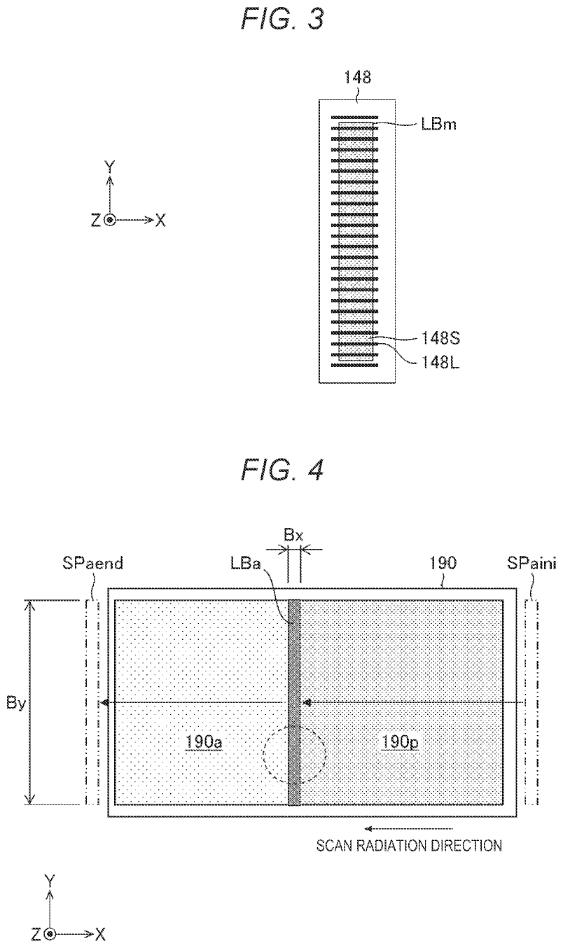

The mask 148 is, for example, a mask formed of a synthetic quartz substrate which transmits ultraviolet light and on which a pattern formed of a metal or dielectric multilayer film is formed. For example, a line-and-space pattern is formed on the mask 148 (see FIG. 3).

The projection optical system 150 is so disposed as to form an image of the mask 148 on the surface of the radiation receiving object 190 via the window 160. The projection optical system 150 may be a combination lens formed of a plurality of lenses 152, which may form a reduction projection optical system.

The window 160 is disposed in an optical path between the projection optical system 150 and the radiation receiving object 190. The window 160 is disposed in a hole provided in the enclosure 164, for example, via an O ring that is not shown. The window 160 may be a substrate made of CaF₂ crystal or synthetic quartz, which transmits excimer laser light, and may be coated with reflection suppression films on opposite sides.

The enclosure 164 has an inlet 166 and an outlet 168, via which a nitrogen (N₂) gas enters and exits out of the enclosure 164. The enclosure 164 may be sealed, for example, with O rings that are not shown so that outside air does not enter the enclosure 164. The N₂-gas inlet 166 is connected to an N₂ gas supply source that is not shown.

The radiation optical system 110 and the XYZ-axis stage 172 are fixed to the frame 170. The XYZ-axis stage 172 is a motorized stage configured to move the position where the pulsed laser light is radiated relative to the radiation receiving object 190. The table 174 is fixed onto the XYZ-axis stage 172. The radiation receiving object 190 is fixed onto the table 174.

The radiation receiving object 190 is, for example, a glass substrate coated with amorphous silicon. The description will be made with reference to a silicon thin film, and the semiconductor thin film may be made of at least one of Si, Ge, SiGe, and GeSn.

FIG. 3 is a plan view showing an example of the relationship between the pattern on the mask 148 and a linear beam LBm, with which the mask 148 is illuminated. The pattern on the mask 148 is a line-and-space pattern formed, for example, of line sections 148L, which are each a light blocking section, and space sections 1485, which are each a light transmitting section (non-blocking section), with the two sections alternately arranged. The minor axis direction (X-axis direction) of the linear beam LBm, with which the mask 148 is uniformly illuminated, is parallel to the line direction of the line sections 148L, and the plurality of line sections 148L are arranged at predetermined intervals in the major axis direction (Y-axis direction) of the linear beam LBm.

The laser light radiated onto the radiation receiving object 190 via the mask 148 is a beam group carrying a pattern corresponding to the image of the pattern on mask 148. Since the pattern carried by the laser light radiated onto the radiation receiving object 190 via the mask 148 generally has a rectangular shape as a whole including the light blocking sections of the mask 148, the laser light radiated onto the radiation receiving object 190 is also called a “linear beam”.

Let Bx be the X-axis-direction beam width of the linear beam on the radiation receiving object 190 and By be the Y-axis-direction beam width of the linear beam, and the linear beam satisfies Bx<By (see FIG. 4).

2.2 Operation

The laser annealing controller 180 is configured to read radiation condition parameters at the time of laser annealing. Specifically, the laser annealing controller 180 is configured to read data on fluence Fa, the number of radiated pulses Na, and a repetitive frequency fa on the radiation receiving object 190 in the laser annealing.

A variety of data and signals, such as target pulse energy Et, are transmitted from the laser annealing controller 180 and received by the laser controller 38 and vice versa. The laser annealing controller 180 is configured to cause the laser apparatus 20 to perform adjustment oscillation. The laser controller 38 is configured to receive data on the target pulse energy Et from the laser annealing controller 180.

Upon reception of the data on the target pulse energy Et, the laser controller 38 is configured to close a shutter 36 and control the charger 44 in such a way that the target pulse energy Et is achieved.

The laser controller 38 is configured to cause an internal trigger generator that is not shown to generate an internal trigger signal, which is inputted to the switch 47 of the PPM 46. As a result, the master oscillator 30 performs spontaneous oscillation.

The duration of the pulsed laser light outputted from the master oscillator 30 is stretched by the OPS system 32. The pulsed laser light outputted from the OPS system 32 is sampled by the beam splitter 76 of the monitoring module 34, and pulse energy E is measured.

The laser controller 38 is configured to control charging voltage applied to the charger 44 in such a way that a difference ΔE between the pulse energy E and the target pulse energy Et approaches zero.

The laser controller 38 is configured to transmit an external trigger OK signal to the laser annealing controller 180 to open the shutter 36 when ΔE falls within an acceptable range.

The laser annealing controller 180 is configured to receive the external trigger OK signal from the laser controller 38.

The laser annealing controller 180 is configured to thereafter control the axes X and Y of the XYZ-axis stage 172 in such a way that the position to which the projection optical system 150 transfers the image of the mask 148 is in an initial position.

The laser annealing controller 180 is configured to subsequently control the axis Z of the XYZ-axis stage 172 in such a way that the image of the mask 148 is brought into focus at the position of the surface of the radiation receiving object 190.

The laser annealing controller 180 is configured to calculate transmittance T provided by the attenuator 130 in such a way that the fluence at the position of the surface of the radiation receiving object 190 (that is, position of image of mask 148) is equal to the target fluence Fa.

The laser annealing controller 180 is configured to subsequently control the angles of incidence of the pulsed laser light incident on the two partially reflective mirrors 131 and 132 by using the rotary stages 135 and 136 in such a way that the attenuator 130 provides the transmittance T.

The laser annealing controller 180 is configured to subsequently calculate a movement speed Vx of the XYZ-axis stage 172 in such a way that the number of radiated pulses Na is achieved when the repetitive frequency is fa and the beam width of the linear beam on the radiation receiving object 190 is Bx.

The laser annealing controller 180 is configured to control the XYZ-axis stage 172 in such a way that the table 174 makes uniform speed linear motion at the speed Vx in the X-axis direction. As a result, the linear beam moves on the surface of the radiation receiving object 190 in the uniform speed linear motion at the speed Vx in the direction opposite the direction of the movement of the table 174.

The laser annealing controller 180 is configured to transmit a light emission trigger signal Tr at the repetitive frequency fa during the uniform speed linear motion of the linear beam to the laser controller 38. As a result, the pulsed laser light is outputted from the master oscillator 30 in synchronization with the light emission trigger signal Tr, and the pulsed laser light having passed through the beam splitter 76 of the monitoring module 34 enters the laser annealing apparatus 100 through the optical path tube 25.

The pulsed laser light having entered the laser annealing apparatus 100 is reflected off the high-reflectance mirror 121, passes through the attenuator 130, which attenuates the pulsed laser light, and the attenuated pulsed laser light is reflected off the high-reflectance mirror 122.

The pulsed laser light reflected off the high-reflectance mirrors 122 and 123 at high reflectance enters the illumination optical system 140, which is configured to spatially homogenize the optical intensity of the pulsed laser light, and the homogenized pulsed laser light is incident as the linear beam LBm on the mask 148.

The pulsed laser light having passed through the mask 148 enters the projection optical system 150, which is configured to project the pulsed laser light on the surface of the radiation receiving object 190. The pulsed laser light thus passes through the projection optical system 150 and is radiated to the radiation receiving object 190 in the area where the image of the mask 148 is transferred and brought into focus. As a result, the portion irradiated with the pulsed laser light out of the surface of the radiation receiving object 190 undergoes laser annealing.

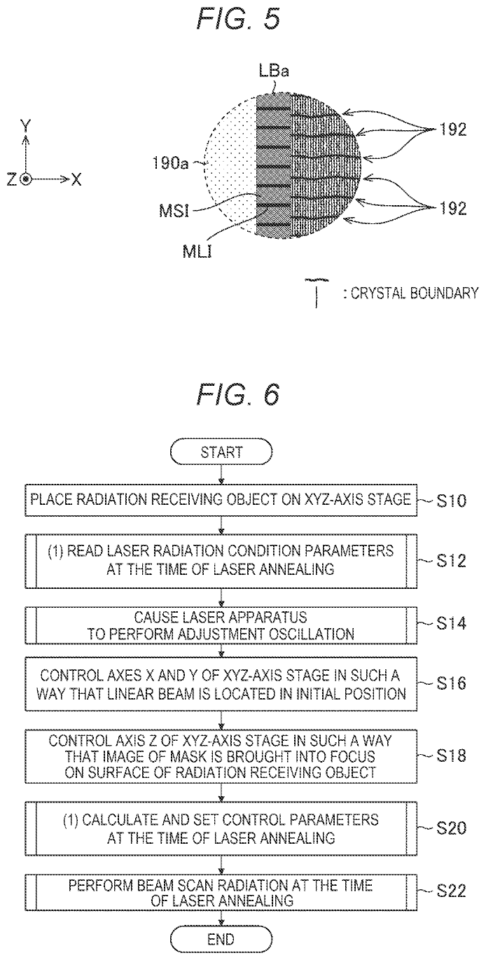

FIG. 4 is a plan view showing an example of linear beam scan radiation performed on a radiation receiving object. FIG. 5 is an enlarged view of the portion surrounded by the broken circle in FIG. 4.

A linear beam LBa radiated onto the surface of the radiation receiving object 190 has the pattern of an image of the line-and-space pattern on the mask 148 described with reference to FIG. 3. The linear beam LBa radiated onto the surface of the radiation receiving object 190 has the beam width Bx in the X-axis direction and the beam width By in the Y-axis direction, as shown in FIG. 4. The linear beam LBa moves relative to the radiation receiving object 190 when the XYZ-axis stage 172 moves. Moving the XYZ-axis stage 172 in the positive direction of the axis X moves the linear beam LBa on the surface of the radiation receiving object 190 in the negative direction of the axis X (leftward in FIG. 4).

FIG. 4 shows scan radiation in which the linear beam LBa is moved relative to the radiation receiving object 190 from a scan radiation initial position SPaini to a scan radiation end position SPaend to radiate the laser light onto the surface of the radiation receiving object 190. The direction of the movement of the linear beam LBa from the scan radiation initial position SPaini toward the scan radiation end position SPaend is called a “scan radiation direction” at the time of the laser annealing.

In FIG. 4, the area where the linear beam LBa has passed, that is, the area where the scan radiation has been performed out of the surface of the radiation receiving object 190 is a crystallized area 190p where the amorphous silicon has melted and the silicon has been poly-crystalized by crystal growth. The crystallized area 190p forms a polysilicon film. The area where the linear beam LBa has not passed, that is, the area where the scan radiation has not been performed out of the surface of the radiation receiving object 190 is an amorphous area 190a, which has not yet been irradiated with the laser light and remains amorphous.

FIG. 5 is an enlarged view of the portion surrounded by the broken circle in FIG. 4. The fluence in line sections MLI of the pattern of the image of the mask 148 in the linear beam LBa, with which the radiation receiving object 190 is irradiated, is lower than the fluence in space sections MSI of the pattern. The laser-annealed crystal therefore has the following form: Crystal nuclei are generated in the positions corresponding to the line sections MLI of the surface of the radiation receiving object 190; and a large grain boundary 192 is generated in a substantially Y-axis-direction central portion of each of the space sections MSI between the line sections MLI, as shown in FIG. 5.

When the scan radiation is performed while the linear beam LBa is moved in the negative direction of the axis X, and the position of the linear beam LBa with respect to the radiation receiving object 190 reaches the scan radiation end position Spaend (see FIG. 4), the XYZ-axis stage 72 is caused to stop moving.

2.3 Example of Operation

FIG. 6 is a flowchart showing an example of the operation of the laser annealing system 10. The processes and operations shown in the flowchart of FIG. 6 are achieved when a processor configured to function as the laser annealing controller 180 executes a program.

In step S10, the radiation receiving object 190 is placed on the table 174 on the XYZ-axis stage 172. The radiation receiving object 190 may be placed on the table 174 by a workpiece conveying robot or any other automatic conveyer that is not shown.

In step S12, the laser annealing controller 180 performs (1) reading the laser radiation condition parameters at the time of the laser annealing. The laser radiation condition parameters at the time of the laser annealing are called “laser annealing condition parameters”.

In step S14, the laser annealing controller 180 causes the laser apparatus 20 to perform the adjustment oscillation. The laser annealing controller 180 causes the laser apparatus 20 to perform the adjustment oscillation at a repetitive frequency fa in such a way that the target pulse energy Et is achieved.

In step S16, the laser annealing controller 180 controls the XYZ-axis stage 172 to move in the X-axis and Y-axis directions in such a way that the position of the linear beam LBa on the radiation receiving object 190 is an initial position.

In step S18, the laser annealing controller 180 controls the XYZ-axis stage 172 to move in the axis Z in such a way that the image of the mask 148 is brought into focus on the surface of the radiation receiving object 190.

In step S20, the laser annealing controller 180 performs (1) calculating and setting control parameters at the time of the laser annealing. Specifically, the laser annealing controller 180 calculates transmittance Ta provided by the attenuator 130 and set the transmittance Ta in such a way that the fluence Fa is achieved when the linear beam width in the minor axis direction is Bx. The laser annealing controller 180 calculates the movement speed Vx of the XYZ-axis stage 172 and set the movement speed Vx in such a way that the number of radiated pulses Na is achieved when the linear beam width in the minor axis direction is Bx.

In step S22, the laser annealing controller 180 performs the beam scan radiation at the time of the laser annealing in accordance with the control parameters set in step S20. In the beam scan radiation, the radiation receiving object 190 is irradiated with the pulsed laser light under the set conditions including the repetitive frequency fa, the fluence Fa, and the number of radiated pulses Na.

After step S22, the laser annealing controller 180 terminates the flowchart of FIG. 6.

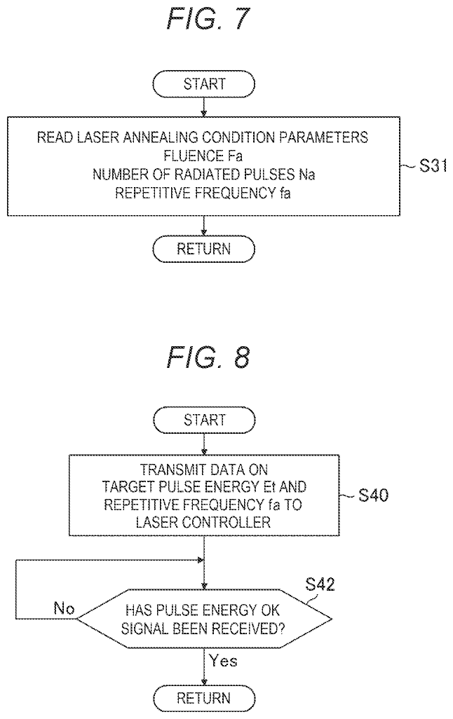

FIG. 7 is a flowchart showing an example of the subroutine applied to step S12 in FIG. 6. That is, FIG. 7 shows an example of the contents of the processes carried out in the step of (1) reading the laser radiation condition parameters at the time of the laser annealing.

In step S31 in FIG. 7, the laser annealing controller 180 reads the laser annealing condition parameters. For example, the laser annealing controller 180 reads the data on the fluence Fa, the number of radiated pulses Na, and the repetitive frequency fa on the radiation receiving object 190 in the laser annealing. The number of radiated pulses Na is an integer greater than or equal to two. After step S31, the laser annealing controller 180 returns to the flowchart of FIG. 6.

FIG. 8 is a flowchart showing an example of the subroutine applied to step S14 in FIG. 6. That is, FIG. 8 shows an example of the contents of the processes carried out in the step of performing the adjustment oscillation of the laser apparatus.

In step S40 in FIG. 8, the laser annealing controller 180 transmits the data on the target pulse energy Et and the repetitive frequency fa to the laser controller 38. The data on the target pulse energy Et and the repetitive frequency fa in this case are preferably rated data that allow the laser apparatus 20 to stably operate. For example, the target pulse energy Et may fall within a range from 30 to 100 millijoules. The repetitive frequency fa may fall within a range from 600 to 6000 Hz. The laser annealing controller 180 may store in advance the rated pulse energy of the pulsed laser light from the laser apparatus 20 as the target pulse energy Et and use the stored value.

In step S42, the laser annealing controller 180 evaluates whether or not a pulse energy OK signal has been received from the laser controller 38. The evaluation process in step S42 corresponds, for example, to evaluation of whether or not the difference between the pulse energy E of the pulsed laser light outputted from the laser apparatus 20 and the target pulse energy Et falls within the acceptable range.

The laser annealing controller 180 repeats step S42 until the result of the evaluation in step S42 becomes Yes. When the result of the evaluation in step S42 is Yes, the laser annealing controller 180 leaves the subroutine in FIG. 8 and returns to the flowchart of FIG. 6.

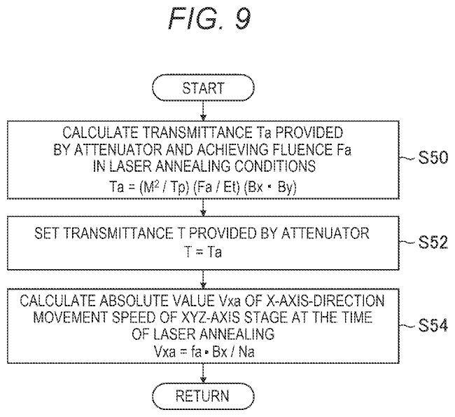

FIG. 9 is a flowchart showing an example of the subroutine applied to step S20 in FIG. 6. That is, FIG. 9 shows an example of the contents of the processes carried out in the step of (1) calculating and setting the control parameters at the time of the laser annealing.

In step S50 in FIG. 9, the laser annealing controller 180 calculates the transmittance Ta provided by the attenuator 130 and achieving the fluence Fa in the laser annealing conditions.

The fluence at the surface of the radiation receiving object 190 is expressed by Expression (2) below.

F=M⁻²(T·Tp·Et)/(Bx·By) (2)

M in the expression represents the magnification factor of the projection optical system 150. M may range, for example, from 1 to ⅕.

Tp in the expression represents the transmittance provided by the optical system along which the pulsed laser light outputted from the laser apparatus 20 reaches the radiation receiving object 190 when the attenuator 130 provides the maximum transmittance.

Expression (2) derives Expression (3) below as a formula for calculating the transmittance Ta provided by the attenuator 130.

Ta=(M²/Tp)(Fa/Et)(Bx·By) (3)

The laser annealing controller 180 determines from Expression (3) the transmittance Ta provided by the attenuator 130.

In step S52, the laser annealing controller 180 sets the transmittance T provided by the attenuator 130 at Ta. That is, the laser annealing controller 180 controls the angles of the partially reflective mirrors 131 and 132 in such a way that the transmittance T provided by the attenuator 130 is Ta.

Thereafter, in step S54, the laser annealing controller 180 calculates an absolute value Vxa of the X-axis-direction movement speed of the XYZ-axis stage 172 at the time of the laser annealing. Vxa can be calculated from Expression (4) below.

Vxa=fa·Bx/Na (4)

Expression (4) is derived as follows.

Let Vxa be the absolute value of the X-axis-direction movement speed of the XYZ-axis stage 172, and the number of radiated pulses Na at the time of the laser annealing is expressed by Expression (5) below.

Na=fa·Bx/Vxa (5)

Na is the number of pulses by which the pulsed laser light is radiated to a single position (Na≥2).

The absolute value Vxa of the movement speed can be determined from Expression (4), which is a deformed version of Expression (5).

After step S54, the laser annealing controller 180 terminates the flowchart of FIG. 9 and returns to the flowchart of FIG. 6.

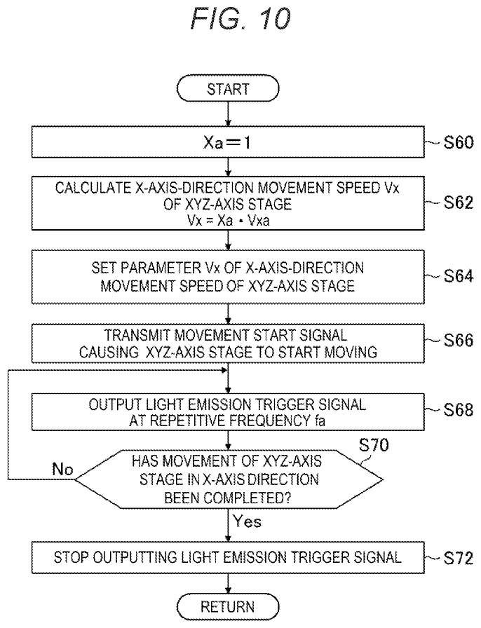

FIG. 10 is a flowchart showing an example of the subroutine applied to step S22 in FIG. 6. That is, FIG. 10 shows an example of the contents of the processes carried out in the beam scan radiation step at the time of the laser annealing.

In step S60 in FIG. 10, the laser annealing controller 180 sets the value of a parameter Xa, which specifies the direction of the movement of the XYZ-axis stage 172 along the axis X, at “Xa=1”. “Xa=1” represents that the XYZ-axis stage 172 is moved in the “positive direction” of the axis X.

In step S62, the laser annealing controller 180 calculates the X-axis-direction movement speed Vx of the XYZ-axis stage 172. Vx is determined in accordance with Expression (6) below.

Vx=Xa·Vxa (6)

In step S64, the laser annealing controller 180 sets a parameter Vx of the X-axis-direction movement speed of the XYZ-axis stage 172 in accordance with the result of the calculation in step S62. In practice, the parameter is so set that acceleration, the uniform speed linear motion, and deceleration are each performed for a predetermined period in correspondence with the distance over which the beam scan is performed. In the description, a case where the absolute value of the speed of the XYZ-axis stage 172 in the uniform speed linear motion is Vxa is presented by way of example for simplification of the description.

When Vx specified by Expression (6) has a positive value, the XYZ-axis stage 172 is moved in the positive direction of the axis X. As a result, the linear beam LBa moves on the radiation receiving object 190 relative thereto in the negative direction of the axis X.

In step S66, the laser annealing controller 180 transmits a movement start signal causing the XYZ-axis stage 172 to start moving. The movement start signal is a control signal instructing the XYZ-axis stage 172 to start moving. The XYZ-axis stage 172 starts moving in accordance with the movement start signal transmitted from the laser annealing controller 180.

In step S68, the laser annealing controller 180 outputs a light emission trigger signal at the repetitive frequency fa.

In step S70, the laser annealing controller 180 evaluates whether or not the movement of the XYZ-axis stage 172 in the X-axis direction has been completed. For example, the laser annealing controller 180 evaluates whether or not the XYZ-axis stage 172 has reached the scan radiation end position SPaend described in FIG. 4. When the result of the evaluation in step S70 is No, the laser annealing controller 180 returns to step S68. Steps S68 to S70 are repeated until the movement of the XYZ-axis stage 172 in the X-axis direction is completed. For the period from the start of the beam scan to the end thereof, the laser annealing controller 180 outputs the light emission trigger signal at the repetitive frequency fa to the laser controller 38 during the uniform speed linear motion of the XYZ-axis stage 172 in the X-axis direction. The pulsed laser light is thus radiated at the repetitive frequency fa to a scan radiation receiving area of the radiation receiving object 190.

When the result of the evaluation in step S70 is Yes, that is, when the beam scan radiation performed on one scan radiation receiving area is completed and the movement of the XYZ-axis stage 172 in the X-axis direction is completed, the laser annealing controller 180 proceeds to step S72 and stops outputting the light emission trigger signal. The laser apparatus 20 thus stops outputting the pulsed laser light.

After step S72, the laser annealing controller 180 terminates the flowchart of FIG. 10 and returns to the flowchart of FIG. 6.

2.4 Others

The case described with reference to FIGS. 2 to 10 shows a method for performing the laser annealing by guiding the pattern of an image of the mask 148 to the radiation receiving object 190 and scanning and irradiating the surface of the radiation receiving object 190 with the pattern of the image of the mask 148. The laser light radiation method for performing laser annealing is, however, not limited to the case described above. For example, the scan radiation method may be replaced with a step-and-repeat method in which the XYZ-axis stage 172 is first fixed and the XYZ-axis stage 172 is then moved to and fixed in a next position when the number of radiated pulses Na is reached followed by the radiation of the pulsed laser light.

### 3. Problems

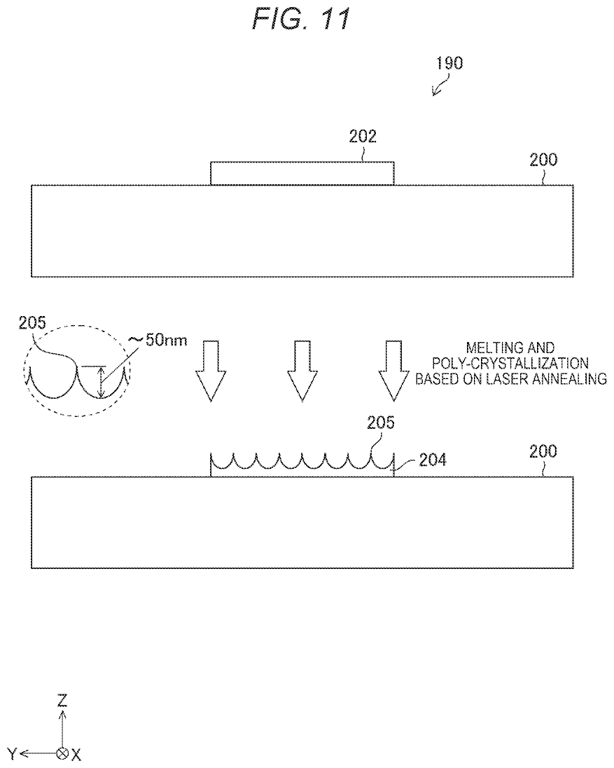

FIG. 11 is a diagrammatic view of a method for manufacturing a semiconductor crystalline thin film based on laser annealing. The following description shows an example of the radiation receiving object 190 formed of a glass substrate 200 on which an amorphous silicon film 202 is disposed. When the amorphous silicon film 202 is irradiated with pulsed laser light so that laser annealing is performed thereon, the silicon is melted and poly-crystalized, whereby a polysilicon film 204, which is a semiconductor crystalline thin film, is produced.

Protrusions (raised portions) called ridges 205 having a size of about 50 nm in the process of melting and poly-crystalizing the silicon are, however, generated on the surface of the crystal generated by the laser annealing. For example, when the amorphous silicon film 202 has a film thickness of 50 nm, ridges having a height ranging from 50 to 70 nm are generated in some cases on the surface of the polysilicon film 204 formed by the laser annealing performed on the amorphous silicon film 202.

Since the ridges 205 greatly affect the characteristics of the semiconductor element formed by using the polysilicon film 204, it is desirable to suppress the height of the ridges 205. A problem caused by the ridges 205 is also described in paragraph 0052 in JP-A-2007-287866. For example, the ridges 205 affect the threshold voltage of a thin film transistor formed by using the polysilicon film 204, so that the threshold voltage varies, and it may be difficult to lower the power supply voltage. In a liquid crystal display element using such a thin film transistor, for example, it is difficult to reduce the power consumed by the liquid crystal display element.

### 4. First Embodiment

4.1 Overview of Method for Manufacturing Semiconductor Crystalline Thin Film

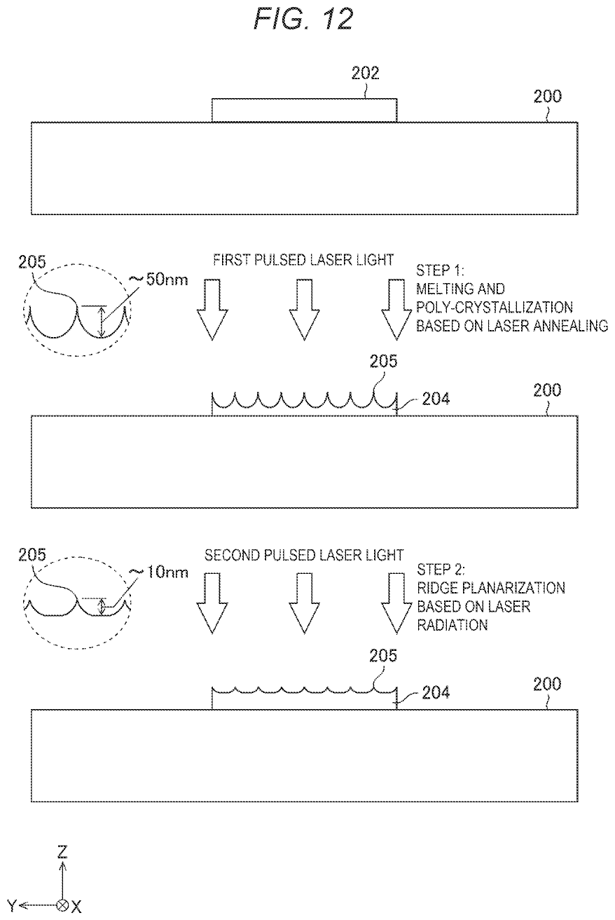

FIG. 12 is a diagrammatic view showing an example of a method for manufacturing a semiconductor crystalline thin film according to a first embodiment. The method for manufacturing the semiconductor crystalline thin film according to the first embodiment includes radiating first pulsed laser light to the amorphous silicon film 202 to poly-crystalize the amorphous silicon (step 1) and radiating second pulsed laser light to the ridges 205 of the polycrystalline polysilicon film 204 generated by the radiation of the first pulsed laser light to planarize the ridges 205 (step 2). The phrase “planarize the ridges” means reducing the height of the ridges.

Step 1 is the step of melting and poly-crystallization based on laser annealing. Step 2 is the step of laser-radiation-based planarization of the polycrystalline ridges generated in step 1. In the description, the operation in step 1 is called “laser annealing”, and the operation in step 2 is called “ridge planarization” for convenience of the description.

The laser light radiation conditions at the time of the laser annealing include the fluence Fa, a pulse duration ΔTa, and the number of radiated pulses Na.

The laser light radiation conditions at the time of the ridge planarization include fluence Fr, a pulse duration ΔTr, and the number of radiated pulses Nr.

As the relationship between the radiation conditions at the time of the laser annealing and the radiation conditions at the time of the ridge planarization, the pulse duration ΔTr of the second pulsed laser light is assumed to be shorter than the pulse duration ΔTa of the first pulsed laser light. That is, ΔTr<ΔTa.

When a polycrystalline Si thin film having ridges formed thereon is irradiated with pulsed laser light having an appropriate pulse width and fluence, electric field concentration due to the shape effect of the ridge portion causes the laser pulse energy applied to the ridge portion to be greater than the pulse energy applied to the other area. As a result, it is believed that the crystal state of the ridge portion can be improved so that the height thereof can be controlled by partially melting the ridge portion and therearound without melting and solidifying the entire film.

It is preferable as an additional condition that the fluence Fr of the second pulsed laser light is smaller than the fluence Fa of the first pulsed laser light. That is, Fr<Fa is preferably satisfied. As another additional condition, the number of radiated pulses Nr of the second pulsed laser light is smaller than the number of radiated pulses Na of the first pulsed laser light. That is, Nr<Na is preferably satisfied.

That is, the laser radiation conditions for the laser annealing in step 1 are so set that the amorphous silicon is fully melted, and the laser radiation conditions for the ridge planarization in step 2 are so set that the height of the polysilicon ridge portion generated by the laser-annealing-based poly-crystallization is reduced. Performing the laser radiation in step 2 can reduce the height of the ridges 205 produced by the poly-crystallization in step 1 to a value smaller than 10 nm.

4.2 Example of Radiation Conditions

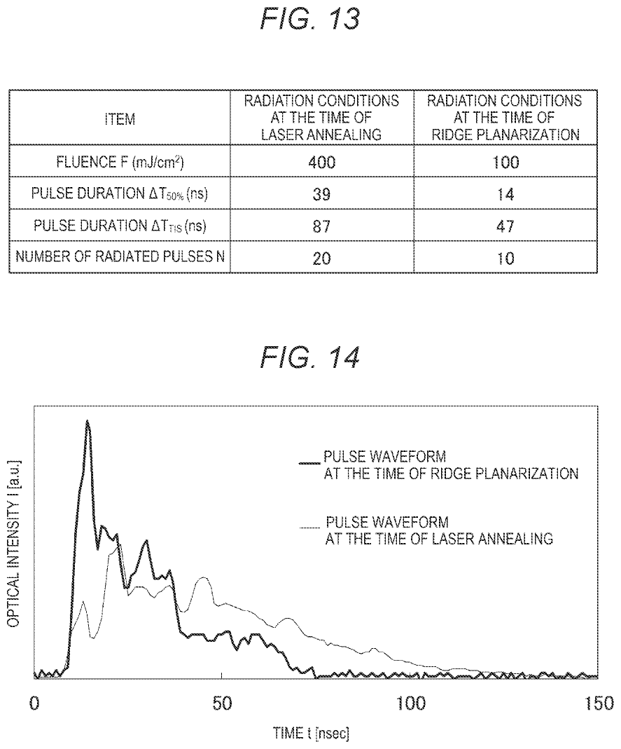

FIG. 13 is a table showing an example of the radiation conditions applied to a test of generation of a semiconductor crystalline thin film. It is ascertained that the radiation condition combination shown in FIG. 13 allows generation of a semiconductor crystalline thin film with the height of the ridges suppressed to a value smaller than 10 nm. A pulse duration ΔTr_{50%}=14 ns, which is the full width at half maximum, of the pulsed laser light for ridge planarization is 35.8% of a pulse duration ΔTa₅₀%=39 ns, which is the full width at half maximum, of the pulsed laser light for laser annealing in FIG. 13. The pulse duration, which is the full width at half maximum, of the pulsed laser light for ridge planarization is preferably smaller than or equal to 40% of the pulse duration of the pulsed laser light for laser annealing.

A TIS pulse duration ΔTr_{TIS}=47 ns of the pulsed laser light for ridge planarization is 54.0% of a TIS pulse duration ΔTa_{TIS}=87 ns of the pulsed laser light for laser annealing in FIG. 13. The TIS pulse duration of the pulsed laser light for ridge planarization is preferably smaller than or equal to 60% of the TIS pulse duration of the pulsed laser light for laser annealing.

Although not shown in FIG. 13, preferred examples of the combination of the fluence Fa and the number of radiated pulses Na as the radiation conditions at the time of the ridge planarization may include (Fa, Na)=(50, 20), (100, 10), (150, 10), and (200, 1). The unit of the fluence Fa is millijoule per square centimeters [mJ/cm²], as in FIG. 13.

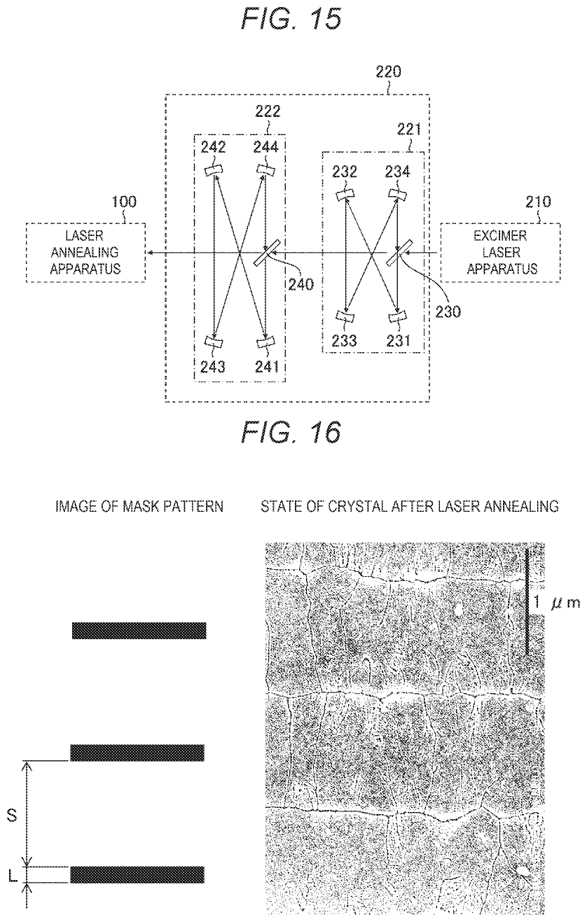

FIG. 14 shows graphs illustrating examples of the pulse waveform of the laser light used in the test. The pulse waveform at the time of the ridge planarization has a pulse duration shorter than that of the pulse waveform at the time of the laser annealing, as shown in FIG. 14. In FIG. 14, the forefronts of the pulses displayed therein are aligned with each other for comparison purposes. In practice, after the first pulsed laser light is radiated to a position (irradiated area) on the radiation receiving object 190, the second pulsed laser light is radiated to the same position. The timings when the first pulsed laser light and the second pulsed laser light are radiated to the same position on the radiation receiving object 190 therefore differ from each other.

That is, after the radiation of the first pulsed laser light poly-crystalizes the silicon film, that is, after the ridges 205 are formed, the radiation of the second pulsed laser light to the area of the poly-crystalized silicon film starts. The period for which the radiation of the first pulsed laser light melts and poly-crystallizes the silicon film is about 200 ns. Therefore, for example, at least 200 ns after the radiation timing of the first pulsed laser light, which is formed of the pulses for laser annealing (that is, after crystallization), the second pulsed laser light, which is formed of the pulses for ridge planarization, may be radiated to the same area (location) as the area to which the first pulsed laser light is radiated. The ridges 205 formed by the poly-crystallization can thus be partially melted and planarized.

FIG. 15 shows an example of the configuration of the optical pulse stretcher (OPS) system for adjusting the pulse duration. The pulse waveform at the time of the laser annealing shown in FIG. 14 can be achieved by using an OPS system 220 in FIG. 15. Further, the pulse waveform at the time of the ridge planarization shown in FIG. 14 can be achieved by blocking the portion that covers a delaying optical path in the OPS system 220 in FIG. 15.

The OPS system 220 shown in FIG. 15 includes a first OPS 221 and a second OPS 222. The first OPS 221 and the second OPS 222 may each have the same configuration as the configuration of the OPS system 32 described with reference to FIG. 2. The first OPS 221 includes a beam splitter 230 and concave mirrors 231 to 234. A delaying optical path length L(1) achieved by the first OPS 221 is, for example, L(1)=3 m (meters).

The second OPS 222 includes a beam splitter 240 and concave mirrors 241 to 244. A delaying optical path length L(2) achieved by the second OPS 222 is, for example, L(2)=7 m. The second OPS 222 is so disposed that the laser light having passed through the beam splitter 230 in the first OPS 221 is incident on the beam splitter 240 in the second OPS 222.

The OPS system 220 is disposed in an optical path between an excimer laser apparatus 210 and the laser annealing apparatus 100. The excimer laser apparatus 210 may, for example, be the master oscillator 30 described with reference to FIG. 2.

4.3 Examples of Mask Pattern and Crystal Growth

FIG. 16 shows examples of the mask pattern and crystal growth. FIG. 16 shows an example of the image of the mask pattern and an example of the state of the crystal after the laser annealing. The state of the crystal shown in FIG. 16 is the state after the laser annealing in a case where the image of the mask pattern with which the radiation receiving object 190 is irradiated has a line width L=0.15 μm and a space width S=1 μm.

The left portion of FIG. 16 shows the image of the mask pattern projected onto the surface of the radiation receiving object 190. The right portion of FIG. 16 shows the state of the crystal after the laser annealing in the position corresponding to the image of the mask pattern. The right portion of FIG. 16 is an example of an image of a sample observed under a scanning electron microscope (SEM) with the ridge portion removed from the sample by etching for ease of observation of the ridge portion (grain boundaries). In the right portion of FIG. 16, the lines that each look like a “crack” are the grain boundaries. A thick grain boundary is produced in a substantially middle position in each of the space portions of the mask pattern image, as shown in FIG. 16.

After the radiation of the pulses for the laser annealing, the pulses for ridge planarization are radiated, for example, after at least 200 ns. The ridges are thus partially melted and planarized. The “planarization” means that the height of the ridges is suppressed to a value within an acceptable range (for example, smaller than 10 nm), that is, the planarity is improved.

4.4 Configuration of Laser Annealing System

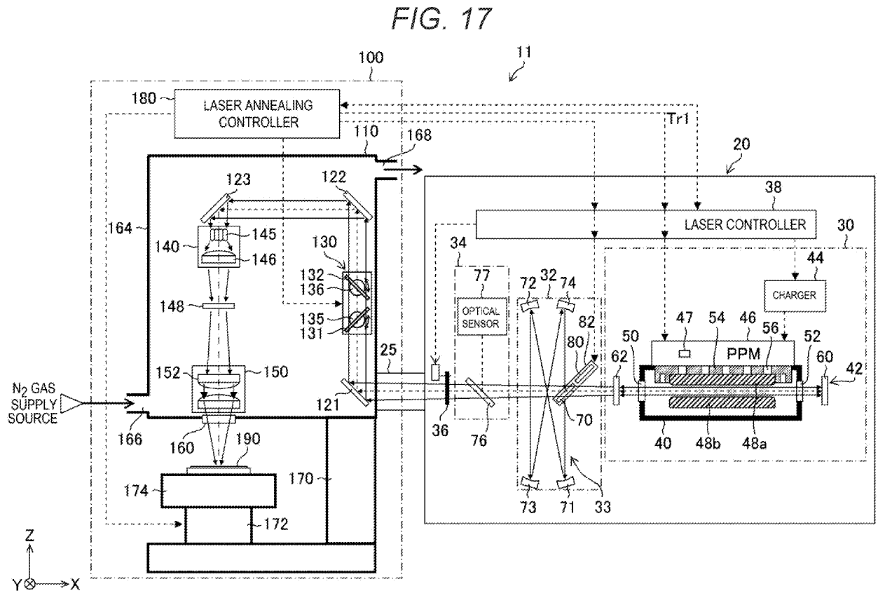

FIG. 17 schematically shows the configuration of a laser annealing system 11 according to the first embodiment. Differences in configuration between FIGS. 17 and 2 will be described. The configuration of the laser annealing system 11 shown in FIG. 17 differs from the configuration in FIG. 2 in that the laser annealing system 11 includes an optical element switching unit 82, which can replace the beam splitter 70 of the OPS system 32 with a window 80.

4.5 Operation

The operation at the time of the laser annealing is the same as the operation in the example in FIG. 2. At the time of the ridge planarization, the scan radiation is performed by changing the radiation conditions at the time of the laser annealing to those at the time of the ridge planarization and moving the XYZ-axis stage 172 in the negative direction of the axis X. It is, however, noted that the optical element switching unit 82 of the OPS system 32 is controlled to change the pulse waveform in the laser annealing to that in the ridge planarization and vice versa.

That is, the laser annealing controller 180 is configured to control the optical element switching unit 82 via the laser controller 38 in such a way that the beam splitter 70 is placed in the optical path at the time of the laser annealing whereas the window 80 is placed in the optical path in place of the beam splitter 70 at the time of the ridge planarization.

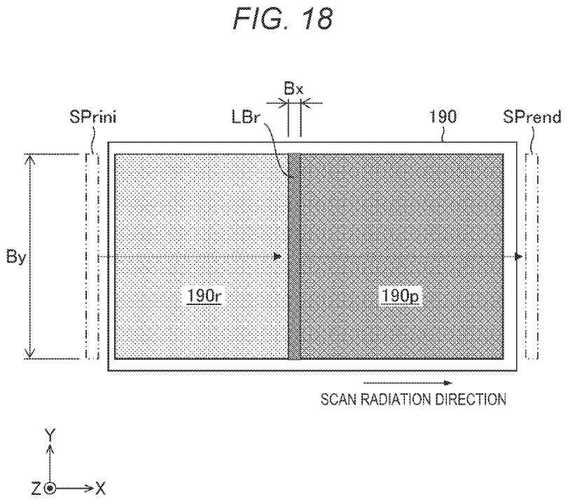

FIG. 18 is a plan view showing an example of the beam scan radiation at the time of the ridge planarization in the first embodiment. A linear beam LBr radiated onto the surface of the radiation receiving object 190 at the time of the ridge planarization carries an image of the line-and-space pattern on the mask 148 described with reference to FIG. 3. The linear beam LBr radiated onto the surface of the radiation receiving object 190 has the X-axis-direction beam width Bx and the Y-axis-direction beam width By, as shown in FIG. 18. The linear beam LBr moves relative to the radiation receiving object 190 when the XYZ-axis stage 172 moves. In the description, the XYZ-axis stage 172 is moved in the negative direction of the axis X to move the linear beam LBr on the surface of the radiation receiving object 190 in the positive direction of the axis X (rightward in FIG. 18).

FIG. 18 shows the scan radiation in which the linear beam LBr is moved relative to the radiation receiving object 190 from a scan radiation initial position SPrini to a scan radiation end position SPrend to radiate the laser light to the surface of the radiation receiving object 190. The direction of the movement of the linear beam LBr from the scan radiation initial position SPrini toward the scan radiation end position SPrend is called a “scan radiation direction at the time of the ridge planarization”. The scan radiation initial position SPrini at the time of the ridge planarization may be the scan radiation end position SPaend at the time of the laser annealing described with reference to FIG. 4. The scan radiation end position SPrend at the time of the ridge planarization shown in FIG. 18 may be the scan radiation initial position SPaini at the time of the laser annealing described with reference to FIG. 4.

In FIG. 18, the area through which the linear beam LBr has passed, that is, the area where the scan radiation for ridge planarization has been performed out of the surface of the radiation receiving object 190 is a planarized ridge area 190r, where the ridges have been planarized. The area through which the linear beam LBr has not passed, that is, the area where the scan radiation for ridge planarization has not been performed is the crystallized area 190p where the high ridges remain.

The entire crystallized area 190p can be changed to the planarized ridge area 190r by further moving the linear beam LBr in the state shown in FIG. 18 to the scan radiation end position SPrend.

4.6 Example of Operation

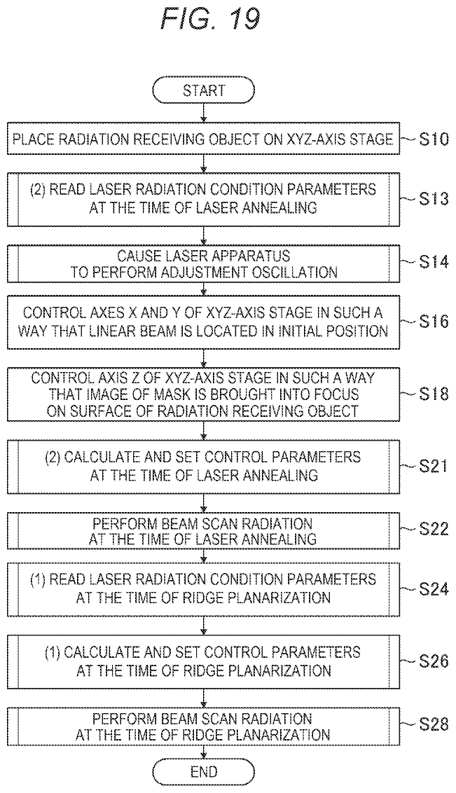

FIG. 19 is a flowchart showing an example of the operation of the laser annealing system 11 according to the first embodiment. Differences between FIGS. 19 and 6 will be described. The flowchart shown in FIG. 19 includes steps S13 and S21 in place of steps S12 and S20 in FIG. 6. Further, steps S24, S26, and S28 are added after step S22.

In step S13, the laser annealing controller 180 performs (2) reading the laser radiation condition parameters at the time of the laser annealing. Steps S14 to S18 after step S13 are the same as those in FIG. 6.

After step S18, the laser annealing controller 180 performs (2) calculating and setting in step S21 the control parameters at the time of the laser annealing. Step S22 after step S21 is the same as that in FIG. 6.

After step S22, the laser annealing controller 180 performs (1) reading the laser radiation condition parameters at the time of the ridge planarization in step S24.

In step S26, the laser annealing controller 180 performs (1) calculating and setting the control parameters at the time of the ridge planarization.

In step S28, the laser annealing controller 180 performs the beam scan radiation at the time of the ridge planarization in accordance with the control parameters set in step S26. In the beam scan radiation, the pulsed laser light is radiated to the radiation receiving object 190 under the set conditions including the repetitive frequency fr, the fluence Fr, and the number of radiated pulses Nr.

After step S28, the laser annealing controller 180 terminates the flowchart of FIG. 19.

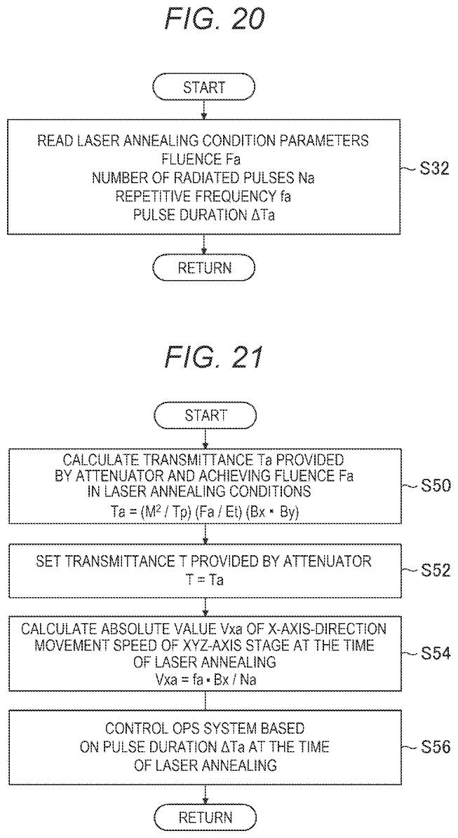

FIG. 20 is a flowchart showing an example of the subroutine applied to step S13 in FIG. 19. That is, FIG. 20 shows an example of the contents of the processes carried out in the step of (2) reading the laser radiation condition parameters at the time of the laser annealing.

In step S32 in FIG. 20, the laser annealing controller 180 reads the laser annealing condition parameters. For example, the laser annealing controller 180 reads the data on the fluence Fa, the number of radiated pulses Na, the repetitive frequency fa, and the pulse duration ΔTa on the radiation receiving object 190 in the laser annealing. The number of radiated pulses Na is assumed to be an integer greater than or equal to two. After step S32, the laser annealing controller 180 returns to the flowchart of FIG. 19.

FIG. 21 is a flowchart showing an example of the subroutine applied to step S21 in FIG. 19. That is, FIG. 21 shows an example of the contents of the processes carried out in the step of (2) calculating and setting the control parameters at the time of the laser annealing. Differences between FIGS. 21 and 9 will be described. The flowchart shown in FIG. 21 further includes step S56 added to steps S50 to S54 in FIG. 9.

In step S56, the laser annealing controller 180 controls the OPS system 32 based on the pulse duration ΔTa at the time of the laser annealing. The laser annealing controller 180 controls the OPS system 32 in such a way that the pulse duration of the pulsed laser light outputted from the OPS system 32 approaches the pulse duration ΔTa required as one of the conditions at the time of the laser annealing. In the configuration shown in FIG. 17, the laser annealing controller 180 controls the optical element switching unit 82 so as to place the beam splitter 70 in the optical path.

After step S56, the laser annealing controller 180 terminates the flowchart of FIG. 21 and returns to the flowchart of FIG. 19.

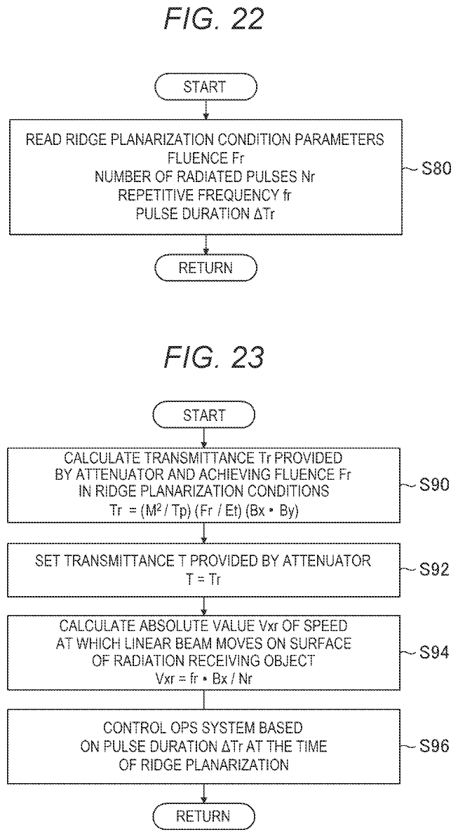

FIG. 22 is a flowchart showing an example of the subroutine applied to step S24 in FIG. 19. That is, FIG. 22 shows an example of the contents of the processes carried out in the step of (1) reading the laser radiation condition parameters at the time of the ridge planarization. The laser radiation condition parameters at the time of the ridge planarization are called “ridge planarization condition parameters”.

In step S80 in FIG. 22, the laser annealing controller 180 reads the ridge planarization condition parameters. For example, the laser annealing controller 180 reads data on the fluence Fr, the number of radiated pulses Nr, the repetitive frequency fr, and the pulse duration ΔTr on the radiation receiving object 190 in the ridge planarization. The number of radiated pulses Nr is an integer greater than or equal to one. After step S80, the laser annealing controller 180 returns to the flowchart of FIG. 19.

FIG. 23 is a flowchart showing an example of the subroutine applied to step S26 in FIG. 19. That is, FIG. 23 shows an example of the contents of the processes carried out in the step of (1) calculating and setting the control parameters at the time of the ridge planarization. In step S90 in FIG. 23, the laser annealing controller 180 calculates the transmittance Tr provided by the attenuator 130 and achieving the fluence Fr in the ridge planarization conditions.

The transmittance Tr provided by the attenuator 130 can be determined by Expression (7) below derived from Expression (2).

Tr=(M²/Tp)(Fr/Et)(Bx·By) (7)

In step S92, the laser annealing controller 180 sets the transmittance T provided by the attenuator 130 at Tr. That is, the laser annealing controller 180 controls the angles of the partially reflective mirrors 131 and 132 in such a way that the transmittance T provided by the attenuator 130 is Tr.

In step S94, the laser annealing controller 180 calculates an absolute value Vxr of the speed at which the linear beam LBr moves on the surface of the radiation receiving object 190 at the time of the ridge planarization. That is, the laser annealing controller 180 calculates the absolute value Vxr of the X-axis-direction movement speed of the XYZ-axis stage 172 at the time of the ridge planarization. Vxr can be calculated from Expression (8) below.

Vxr=fr·Bx/Nr (8)

In step S96, the laser annealing controller 180 controls the OPS system 32 based on the pulse duration ΔTr at the time of the ridge planarization. The laser annealing controller 180 controls the OPS system 32 in such a way that the pulse duration of the pulsed laser light outputted from the OPS system 32 approaches the pulse duration ΔTr required as one of the conditions at the time of the ridge planarization. In the configuration shown in FIG. 17, the laser annealing controller 180 controls the optical element switching unit 82 so as to place the window 80 in the optical path.

After step S96, the laser annealing controller 180 terminates the flowchart of FIG. 23 and returns to the flowchart of FIG. 19.

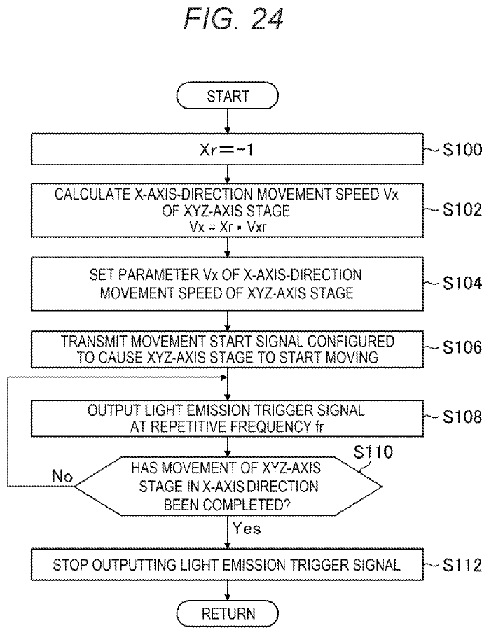

FIG. 24 is a flowchart showing an example of the subroutine applied to step S28 in FIG. 19. That is, FIG. 24 shows an example of the contents of the processes carried out in the beam scan radiation at the time of the ridge planarization. In step S100 in FIG. 24, the laser annealing controller 180 sets the value of a parameter Xr, which specifies the direction of the movement of the XYZ-axis stage 172 in the X-axis direction, at “Xr=−1”. “Xr=−1” represents that the XYZ-axis stage 172 is moved in the “negative direction” of the axis X.

In step S102, the laser annealing controller 180 calculates the X-axis-direction movement speed Vx of the XYZ-axis stage 172. Vx is determined in accordance with Expression (9) below.

Vx=Xr·Vxr (9)

In step S104, the laser annealing controller 180 sets the parameter Vx of the X-axis-direction movement speed of the XYZ-axis stage 172 in accordance with the result of the calculation in step S102. In practice, the parameter is so set that the acceleration, the uniform speed linear motion, and the deceleration are each performed for a predetermined period in correspondence with the distance over which the beam scan is performed. In the description, a case where the absolute value of the speed of the XYZ-axis stage 172 in the uniform speed linear motion is Vxr is presented by way of example for simplification of the description.

In step S106, the laser annealing controller 180 transmits the movement start signal configured to cause the XYZ-axis stage 172 to start moving. When Vx specified by Expression (9) has a negative value, the XYZ-axis stage 172 is moved in the negative direction of the axis X. As a result, the linear beam LBr moves on the surface of the radiation receiving object 190 relative thereto in the positive direction of the axis X.

In step S108 in FIG. 24, the laser annealing controller 180 outputs the light emission trigger signal at the repetitive frequency fr.

In step S110, the laser annealing controller 180 evaluates whether or not the movement of the XYZ-axis stage 172 in the X-axis direction has been completed. The laser annealing controller 180 evaluates whether or not the XYZ-axis stage 172 has reached the scan radiation end position SPrend shown in FIG. 18. When the result of the evaluation in step S110 is No, the laser annealing controller 180 returns to step S108. Steps S108 to S110 are repeated until the movement of the XYZ-axis stage 172 in the X-axis direction is completed. The laser annealing controller 180 outputs the light emission trigger signal at the repetitive frequency fr to the laser controller 38 during the uniform speed linear motion of the XYZ-axis stage 172 in the X-axis direction. The pulsed laser light is thus radiated at the repetitive frequency fr to the scan radiation receiving area of the radiation receiving object 190.

When the result of the evaluation in step S110 is Yes, that is, when the beam scan radiation performed on one scan radiation receiving area is completed and the movement of the XYZ-axis stage 172 in the X-axis direction is completed, the laser annealing controller 180 proceeds to step S112 and stops outputting the light emission trigger signal. The laser apparatus 20 thus stops outputting the pulsed laser light.

After step S112, the laser annealing controller 180 terminates the flowchart of FIG. 24 and returns to the flowchart of FIG. 19.

4.7 Effects and Advantages

In the laser annealing system 11 according to the first embodiment, one laser apparatus can output two types of pulsed laser light having different pulse durations by controlling the OPS system 32, and the laser annealing and the ridge planarization can be performed by using the two types of pulsed laser light.

The laser apparatus 20 in the first embodiment is an example of the “laser system” in the present disclosure. The master oscillator 30 is an example of the “laser oscillator” in the present disclosure. The XYZ-axis stage 172 is an example of the “movement mechanism” in the present disclosure. The laser annealing controller 180 is an example of the “controller” in the present disclosure. The optical system including the illumination optical system 140 and the projection optical system 150 of the radiation optical system 110 is an example of the “radiation optical system” in the present disclosure. The beam splitter 70 and the window 80 in the optical element switching unit 82 are examples of the “optical element” in the present disclosure. The projection optical system 150 is an example of the “transfer optical system” in the present disclosure. The amorphous silicon film 202 is an example of the “amorphous semiconductor” in the present disclosure. The area irradiated with and poly-crystalized by the linear beam LBa for laser annealing is an example of the “area of a semiconductor crystal” in the present disclosure. The polysilicon film 204 is an example of the “semiconductor crystal” and the “semiconductor crystalline thin film” in the present disclosure. The linear beam LBa with which the radiation receiving object 190 is irradiated is an example of the “illumination pattern carried by first pulsed laser light” in the present disclosure, and the linear beam LBr with which the radiation receiving object 190 is irradiated is an example of the “illumination pattern carried by second pulsed laser light” in the present disclosure. The pulse duration ΔTa of the pulsed laser light for laser annealing is an example of the “first pulse duration” in the present disclosure. The pulse duration ΔTr of the pulsed laser light for ridge planarization is an example of the “second pulse duration” in the present disclosure.

4.8 Variations

(1) The first embodiment shows the case where the OPS system 32 is formed of only one OPS 33, but the OPS system may instead be configured to include a plurality of optical pulse stretchers, as shown in FIG. 15. In this case, the plurality of optical pulse stretchers disposed in the OPS system may each be provided with the same optical element switching unit as the optical element switching unit 82 to control the switching of the optical elements from one to the other.

(2) The first embodiment shows the case where the OPS system 32 is disposed in the laser apparatus 20, but the OPS system 32 may instead be disposed in the optical path between the laser annealing apparatus 100 and the laser apparatus 20.

(3) The first embodiment shows the method for performing the laser annealing and the ridge planarization by performing the beam scan radiation, in which the pattern of an image of the mask 148 is moved on the radiation receiving object 190, but not necessarily. For example, the laser radiation using the step-and-repeat method may be performed under the laser annealing radiation conditions at the time of the laser annealing, and the laser radiation using the step-and-repeat method may then be performed under the ridge planarization radiation conditions at the time of the ridge planarization.

### 5. Second Embodiment

5.1 Configuration

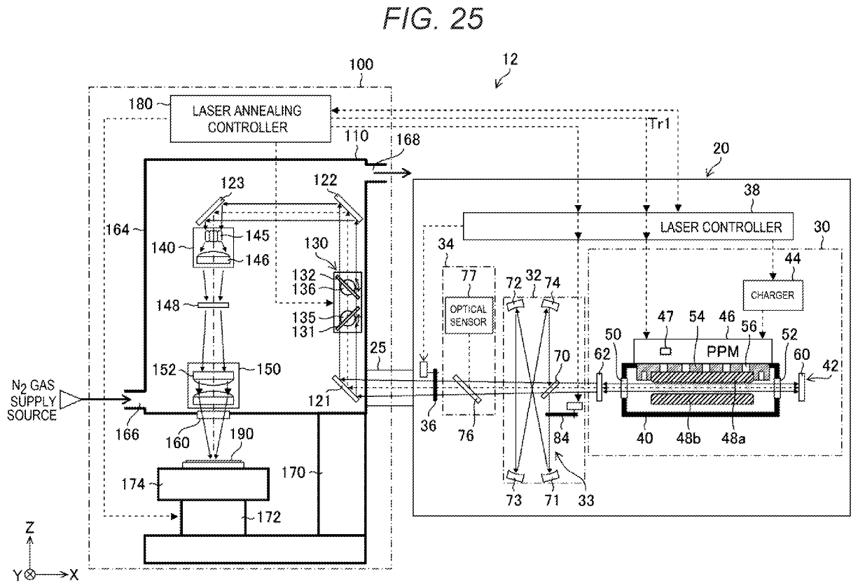

FIG. 25 schematically shows the configuration of a laser annealing system 12 according to a second embodiment. Differences in configuration between FIGS. 25 and 17 will be described. The configuration of the laser annealing system 12 shown in FIG. 25 differs from that shown in FIG. 17 in that a shutter 84 configured to open and close the delaying optical path in the delaying optical path of OPS 33 is disposed in place of the optical element switching unit 82 in FIG. 17. The other configurations are the same as those in FIG. 17. The laser annealing controller 180 is configured to control the operation of opening and closing the shutter 84 via the laser controller 38.

The reflectance provided by the beam splitter 70 of the OPS 33 preferably ranges from 55% to 65% and is more preferably 60%.

5.2 Operation

The laser annealing controller 180 is configured to output a delaying optical path opening/closing control signal configured to operate the shutter 84. The delaying optical path opening/closing control signal transmitted from the laser annealing controller 180 is sent to a driver of the shutter 84 via the laser controller 38.

At the time of the laser annealing, a control signal configured to open the shutter 84 is transmitted from the laser annealing controller 180. When the shutter 84 is opened, the pulsed laser light stretched by the OPS 33 in terms of pulse is radiated to the radiation receiving object 190. The pulsed laser light stretched by the OPS 33 in terms of pulse is an example of the “first pulsed laser light” in the present disclosure.

At the time of the ridge planarization, a control signal configured to close the shutter 84 is transmitted from the laser annealing controller 180. When the shutter 84 is closed, the pulsed laser light that has not been stretched by the OPS 33 in terms of pulse is radiated to the radiation receiving object 190 because the delaying optical path of the OPS 33 is blocked. The pulsed laser light that has not been stretched by the OPS 33 in terms of pulse, that is, the pulsed laser light having passed through the beam splitter 70 when the shutter 84 is closed, is an example of the “second pulsed laser light” in the present disclosure.

5.3 Effects and Advantages

The laser annealing system 12 according to the second embodiment can switch the pulsed laser light for laser annealing and the pulsed laser light for ridge planarization from one to the other and can radiate the selected pulsed laser light by controlling only the operation of opening and closing the shutter 84.

Since the fluence Fr at the time of the ridge planarization is smaller than the fluence Fa at the time of the laser annealing (Fr<Fa), the pulsed laser light having desired fluence Fr at the time of the ridge planarization can be radiated even when the shutter 84 is closed.

### 6. Third Embodiment

6.1 Configuration

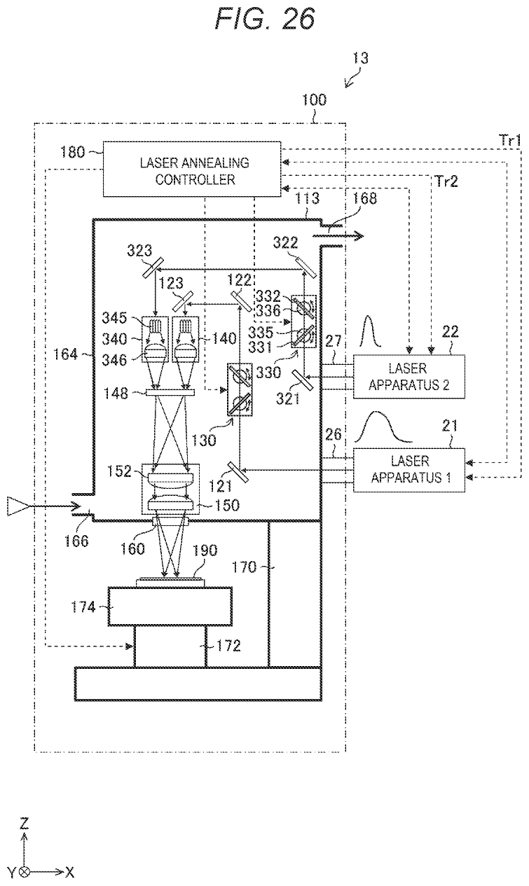

FIG. 26 schematically shows the configuration of a laser annealing system 13 according to a third embodiment. Differences in configuration between FIGS. 26 and 17 will be described. The laser annealing system 13 according to the third embodiment includes a first laser apparatus 21 configured to output the first pulsed laser light for laser annealing, a second laser apparatus 22 configured to output the second pulsed laser light for ridge planarization, a first optical path tube 26, and a second optical path tube 27. The first laser apparatus 21 and the first optical path tube 26 may have the same configurations as those of the laser apparatus 20 and the optical path tube 25 described with reference to FIG. 17. The first optical path tube 26 is disposed in an optical path of the laser light between a laser light exiting port of the first laser apparatus 21 and a first laser light incident port of the laser annealing apparatus 100.

The second laser apparatus 22 is configured to output the second pulsed laser light having a pulse duration shorter than a pulse duration of the first pulsed laser light outputted from the first laser apparatus 21. The second laser apparatus 22 may be a laser apparatus having the configuration of the first laser apparatus 21 from which the OPS system 32 is removed.

The second optical path tube 27 is disposed in an optical path of the laser light between a laser light exiting port of the second laser apparatus 22 and a second laser light incident port of the laser annealing apparatus 100.

In addition to the configuration of the radiation optical system 110 described with reference to FIG. 17, a radiation optical system 113 of the laser annealing system 13 includes high-reflectance mirrors 321 to 323, an attenuator 330, and an illumination optical system 340 configured to radiate the second pulsed laser light for ridge planarization to the radiation receiving object 190.

The high-reflectance mirror 321 is so disposed that the laser light having passed through the second optical path tube 27 passes through the attenuator 330 and is incident on the high-reflectance mirror 322.

The attenuator 330 is disposed in an optical path between the high-reflectance mirror 321 and the high-reflectance mirror 322. The attenuator 330 includes two partially reflective mirrors 331 and 332 and rotary stages 335 and 336 capable of changing the angles of incidence of the light incident on the partially reflective mirrors 331 and 332.

The high-reflectance mirror 322 is so disposed that the laser light having passed through the attenuator 330 is incident on the high-reflectance mirror 323. The high-reflectance mirror 323 is so disposed that the pulsed laser light incident thereon enters a fly-eye lens 345 of the illumination optical system 340.

The illumination optical system 340 includes the fly-eye lens 345 and a condenser lens 346. The illumination optical system 340 is an optical system for uniform illumination of a predetermined illumination receiving area on the mask 148 and is so disposed that the mask 148 is illuminated in the form of Koehler illumination with a rectangular beam.

The fly-eye lens 345 is so disposed, for example, that the focal plane of the fly-eye lens 345 coincides with the front focal plane of the condenser lens 346, and the condenser lens 346 is so disposed, for example, that the rear focal plane of the condenser lens 346 coincides with the position of the mask 148.

Let the linear beam LBa for laser annealing with which the surface of the radiation receiving object 190 is irradiated via the illumination optical system 140 and the projection optical system 150 have a Y-axis-direction beam width Bya and an X-axis-direction beam width Bxa on the surface of the radiation receiving object 190. Let the linear beam LBr for ridge planarization with which the surface of the radiation receiving object 190 is irradiated via the illumination optical system 340 and the projection optical system 150 have a Y-axis-direction beam width Byr and an X-axis-direction beam width Bxr on the surface of the radiation receiving object 190. Let Na be the number of radiated pulses at the time of the laser annealing and Nr be the number of radiated pulses at the time of the ridge planarization. In the third embodiment, the illumination optical system 140 and the illumination optical system 340 are so configured that Bya and Byr are equal to each other (Bya=Byr) and the ratio between Bxa and Bxr is equal to the ratio between Na and Nr (Bxa:Bxr=Na:Nr).

For example, let the Y-axis-direction interval between the lenses of the fly-eye lens 145 of the illumination optical system 140 be equal to that of the fly-eye lens 345 of the illumination optical system 340, and the ratio of the X-axis-direction interval of the lenses of the fly-eye lens 145 to the X-axis-direction interval between the lenses of the fly-eye lens 345 be equal to the ratio of Na to Nr. The focal length of the condenser lens 146 of the illumination optical system 140 may be equal to the focal length of the condenser lens 346 of the illumination optical system 340.

6.2 Operation

The laser annealing performed by radiating the pulsed laser light outputted from the first laser apparatus 21 to the radiation receiving object 190 is the same as the laser annealing performed by the laser annealing system 10 described with reference to FIG. 2. A variety of data and signals, such as the target pulse energy, are transmitted from the laser annealing controller 180 and received by a laser controller that is not shown but controls the second laser apparatus 22 and vice versa. The laser annealing controller 180 is configured to transmit a light emission trigger signal Tr2 to the second laser apparatus 22 in synchronization with a light emission trigger signal Tr1 transmitted to the first laser apparatus 21.

The pulsed laser light outputted from the second laser apparatus 22 passes through the second optical path tube 27, is reflected off the high-reflectance mirror 321, and enters the attenuator 330.

The pulsed laser light having passed through the attenuator 330 enters the illumination optical system 340 via the high-reflectance mirrors 322 and 323.

The pulsed laser light having passed through the illumination optical system 340 is shaped into a linear beam having a rectangular beam shape and homogenized optical intensity and radiated onto the mask 148.

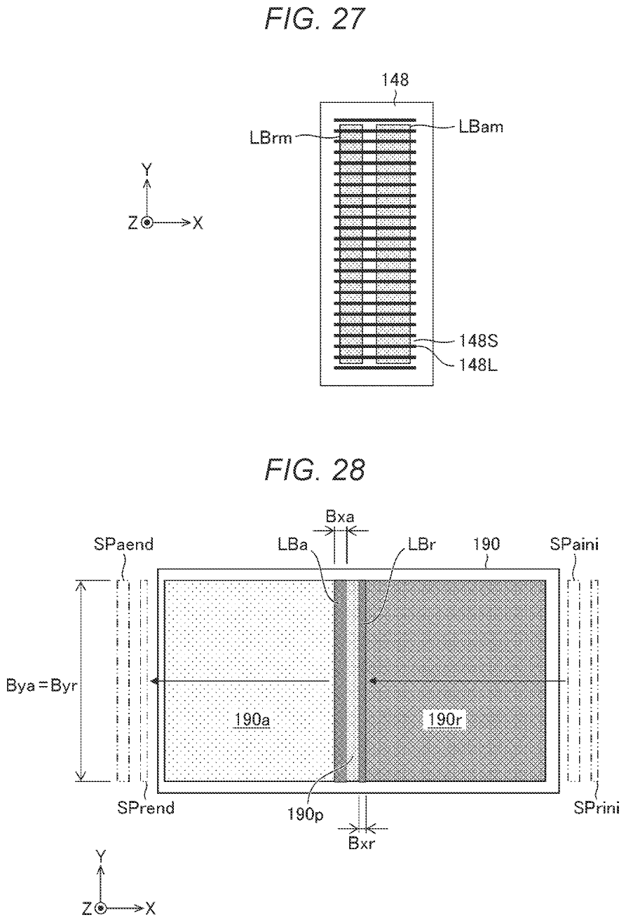

FIG. 27 is a plan view showing an example of the relationship between the pattern on the mask 148 and linear beams LBam and LBrm, with which the mask 148 is illuminated. The linear beam LBam for laser annealing and the linear beam LBrm for ridge planarization are each radiated onto the mask 148, as shown in FIG. 27.

The laser annealing controller 180 is configured to control the transmittance provided by the attenuator 130 in such a way that the fluence of the linear beam LBa for laser annealing on the surface of the radiation receiving object 190 is Fa. The laser annealing controller 180 is further configured to control the transmittance provided by the attenuator 330 in such a way that the fluence of the linear beam LBr for ridge planarization on the surface of the radiation receiving object 190 is Fr.

The X-axis-direction movement speed Vxa of the XYZ-axis stage 172 at the time of the laser annealing is determined by Expression (10) below.

Vxa=fa·Bxa/Na (10)

The X-axis-direction movement speed Vxr of the XYZ-axis stage 172 at the time of the ridge planarization is expressed by Expression (11) below.

Vxr=fr·Bxr/Nr (11)

Vxa=Vxr is achieved by setting the repetitive frequency fa=fr and R=Bxa/Bxr=Na/Nr.

FIG. 28 is a plan view showing an example of the linear beam scan radiation performed on the radiation receiving object 190. The laser annealing and the ridge planarization can be performed by scanning and irradiating the radiation receiving object 190 with two linear beams, the linear beam LBa for laser annealing and the linear beam LBr for ridge planarization, as shown in FIG. 28.

The linear beam LBa for laser annealing radiated to the surface of the radiation receiving object 190 has the pattern of an image of the line-and-space pattern on the mask 148 described with reference to FIG. 27. The linear beam LBa for laser annealing radiated to the surface of the radiation receiving object 190 has the X-axis-direction beam width Bxa and the Y-axis-direction beam width Bya, as shown in FIG. 28. The linear beam LBr for ridge planarization radiated to the surface of the radiation receiving object 190 has the X-axis-direction beam width Bxr and the Y-axis-direction beam width Byr. It is noted that Bya=Byr is satisfied.

The two linear beams LBa and LBr move relative to the radiation receiving object 190 when the XYZ-axis stage 172 moves. The XYZ-axis stage 172 is moved in the positive direction of the axis X to move the linear beams LBa and LBr on the surface of the radiation receiving object 190 in the negative direction of the axis X (leftward in FIG. 28). The linear beam LBa for laser annealing moves from the scan radiation initial position SPaini to the scan radiation end position SPaend on the radiation receiving object 190. The linear beam LBr for ridge planarization follows the movement of the linear beam LBa for laser annealing and moves from the scan radiation initial position SPrini to the scan radiation end position SPrend on the radiation receiving object 190.

In FIG. 28, an area where the linear beam LBa has not passed, that is, the area where the scan radiation has not been performed out of the surface of the radiation receiving object 190 is the amorphous area 190a, which has not yet been irradiated with the laser light and remains amorphous. The area where the linear beam LBa has passed out of the surface of the radiation receiving object 190 is the crystallized area 190p where the silicon has been poly-crystalized by crystal growth. The area through which the linear beam LBr for ridge planarization has passed out of the surface of the radiation receiving object 190 is the planarized ridge area 190r, where the ridges have been planarized. The area through which the linear beam LBa for laser annealing has passed but the linear beam LBr for ridge planarization has not passed out of the surface of the radiation receiving object 190 is the crystallized area 190p where the ridges remain.

When the position of the linear beam LBr for ridge planarization with respect to the radiation receiving object 190 reaches the scanning radiation end position Sprend (see FIG. 28), the XYZ-axis stage 72 is caused to stop moving.

6.3 Effects and Advantages

The laser annealing system 13 according to the third embodiment provides the following effects and advantages as compared with the laser annealing system 11 according to the first embodiment.

[1] The amount of light attenuated by the attenuator 330 at the time of the ridge planarization can be reduced by shaping the two linear beams for laser annealing and ridge planarization via the illumination optical systems 140 and 340 respectively to satisfy R=Bxa/Bxr=Na/Nr. The efficiency at which the pulsed laser light is used is thus improved.

[2] The laser annealing and the ridge planarization in the X-axis direction of the XYZ-axis stage 172 can be performed by one scan radiation operation, whereby the throughput of the laser annealing system is improved.

The combination of the first laser apparatus 21 and the second laser apparatus 22 in the third embodiment is an example of the “laser system” in the present disclosure.

### 7. Fourth Embodiment

7.1 Configuration

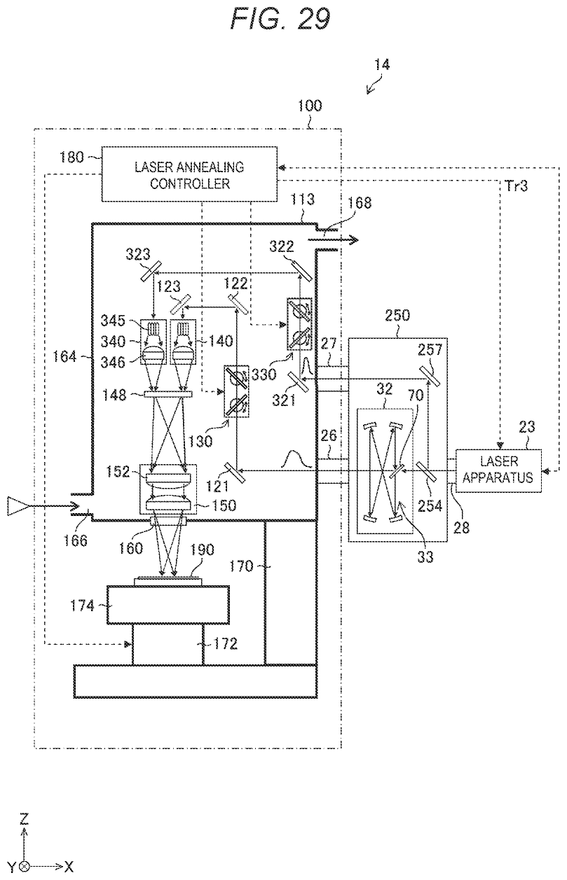

FIG. 29 schematically shows the configuration of a laser annealing system 14 according to a fourth embodiment. Differences in configuration between FIGS. 29 and 26 will be described. The laser annealing system 14 shown in FIG. 29 includes a laser apparatus 23 and a bifurcating system 250 in place of the first laser apparatus 21 and the second laser apparatus 22 in FIG. 26.

The laser apparatus 23 is an excimer laser apparatus including no OPS system. The laser apparatus 23 may, for example, have the configuration of the laser apparatus 20 described with reference to FIG. 2 from which the OPS system 32 is removed and includes the master oscillator 30, the monitoring module 34, and the laser controller 38.

A third optical path tube 28, the bifurcating system 250, the first optical path tube 26, and the second optical path tube 27 are disposed in an optical path between the laser apparatus 23 and the laser annealing apparatus 100. The third optical path tube 28 is disposed in an optical path of the laser light between a laser light exiting port of the laser apparatus 23 and a laser light incident port of the bifurcating system 250.

The bifurcating system 250 includes a beam splitter 254, the OPS system 32, and a high-reflectance mirror 257.

The beam splitter 254 is disposed in an optical path of the laser light between the laser apparatus 23 and the OPS system 32. The beam splitter 254 is coated with a partially reflective film. The light reflected off the beam splitter 245 is incident on the high-reflectance mirror 321 of the laser annealing apparatus 100 via the high-reflectance mirror 257 and the second optical path tube 27.

Reflectance R4 provided by the beam splitter 254 is close to the reflectance calculated by Expression (12) described below.

R4=By·Bxa·Fa/(By·Bxr·Fr)=(Bxa·Fa)/(Bxr·Fr) (12)

The OPS system 32 is disposed in an optical path of the light having passed through the beam splitter 254 and between the high-reflectance mirror 121 of the laser annealing apparatus 100 and the beam splitter 254.

7.2 Operation

The laser annealing controller 180 is configured to transmit a light emission trigger signal Tr3 to the laser apparatus 23. The pulsed laser light outputted from the laser apparatus 23 enters the bifurcating system 250.

The pulsed laser light reflected off the beam splitter 254 is not stretched in terms of pulse but is incident on the high-reflectance mirror 321 via the high-reflectance mirror 257 and the second optical path tube 27. The pulsed laser light reflected off the high-reflectance mirror 321 at high reflectance enters the attenuator 330.

The pulsed laser light having passed through the attenuator 330 enters the illumination optical system 340 via the high-reflectance mirrors 322 and 323.

The pulsed laser light having passed through the illumination optical system 340 is shaped into a linear beam having a rectangular beam shape and spatially homogenized optical intensity and radiated as the linear beam LBrm for ridge planarization onto the mask 148. The relationship between the linear beam LBrm and the pattern on the mask 148 is the same as that in FIG. 27.

On the other hand, the pulsed laser light having passed through the beam splitter 254 of the bifurcating system 250 is stretched by the OPS system 32 in terms of pulse and enters the illumination optical system 140 via the high-reflectance mirror 121, the attenuator 130, and the high-reflectance mirror 122 and 123.

The pulsed laser light having passed through the illumination optical system 140 is shaped into a linear beam having a rectangular beam shape and spatially homogenized optical intensity and radiated as the linear beam LBam for laser annealing onto the mask 148. The relationship between the linear beam LBam and the pattern on the mask 148 is the same as that in FIG. 27.

The operation of the scan radiation for laser annealing and ridge planarization performed on the radiation receiving object 190 in the laser annealing system 14 is the same as the operation of the scan radiation in the third embodiment described with reference to FIG. 28.

7.3 Effects and Advantages

The laser annealing system 14 according to the fourth embodiment is configured to allow the single laser apparatus 23 to perform the laser annealing and the ridge planarization as compared with the configuration in the third embodiment 3 shown in FIG. 26.

Further, the laser annealing system 14 according to the fourth embodiment, in which the reflectance R4 provided by the beam splitter 254 is close to the value calculated by Expression (12), is configured to improve the efficiency at which the pulsed laser light is used, as compared with the laser annealing systems according to the first embodiment (FIG. 17) and the second embodiment (FIG. 25).

The laser apparatus 23 in the fourth embodiment is an example of the “third laser apparatus” in the present disclosure. The combination of the laser apparatus 23 and the bifurcating system 250 is an example of the “laser system” in the present disclosure.

7.4 Variations

(1) In the fourth embodiment shown in FIG. 29, the bifurcating system 250 is disposed between the laser annealing apparatus 100 and the laser apparatus 23, but not necessarily. For example, the bifurcating system 250 may instead be disposed in the laser apparatus 23 or the laser annealing apparatus 100.

(2) The attenuator 330 may not be disposed when the pulse energy of the pulsed laser light from the laser apparatus 23 falls within a controllable range.

### 8. Fifth Embodiment

8.1 Configuration

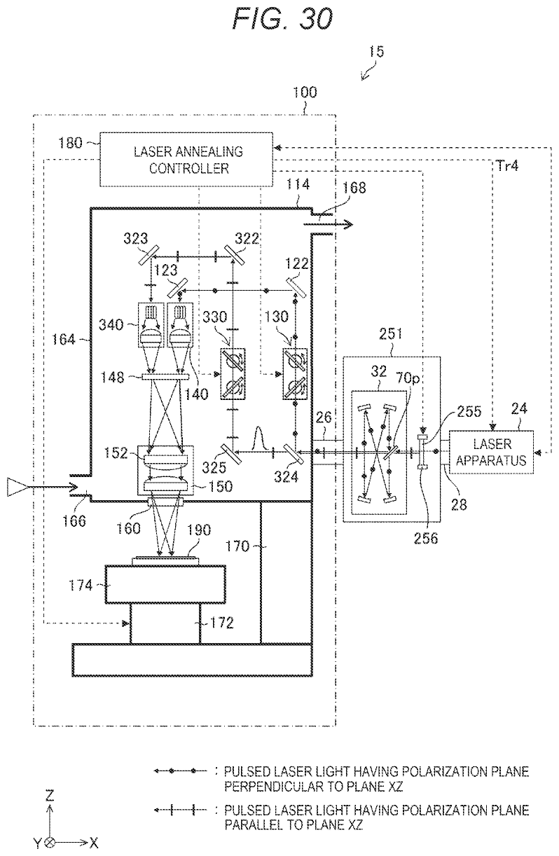

FIG. 30 schematically shows the configuration of a laser annealing system 15 according to a fifth embodiment. Differences in configuration between FIGS. 30 and 29 will be described. The laser annealing system 15 shown in FIG. 30 includes a laser apparatus 24 and a polarization bifurcating system 251 in place of the laser apparatus 23 and the bifurcating system 250 in FIG. 29.

The laser apparatus 24 is an excimer laser apparatus including no OPS system and configured to output pulsed laser light linearly polarized in the direction perpendicular to the plane XZ.

Two windows that are not shown in the optical resonator of the laser apparatus 24 may be disposed at Brewster's angle so that the light polarized in the direction perpendicular to the plane XZ is P-polarized light.

The polarization bifurcating system 251 is disposed in an optical path between the laser apparatus 24 and the laser annealing apparatus 100. In the laser annealing system 15 shown in FIG. 30, the second optical path tube 27 shown in FIG. 27 is omitted.

The polarization bifurcating system 251 includes a retarder 255 and the OPS system 32. The retarder 255 is disposed in an optical path between the OPS system 32 and the laser apparatus 24.

The retarder 255 is a λ/2 plate and is made, for example, of quartz, MgF₂ crystal, or sapphire crystal. The retarder 255 further includes a rotary stage 256 configured to change an angle θ between the optics axis of the retarder 255 and the polarization plane of the pulsed laser light incident on the retarder 255.

The OPS system 32 is disposed in the optical path of the laser light between the laser apparatus 24 and the laser annealing apparatus 100. A beam splitter 70p disposed in the OPS system 32 is coated with a film configured to partially reflect the S-polarized component and transmit the P-polarized component at high transmittance and so disposed that the component polarized in the direction perpendicular to the plane XZ is S-polarized light.

In a radiation optical system 114, the high-reflectance mirrors 121 and 321 in FIG. 29 are removed, and a polarizing beam splitter 324 and a high-reflectance mirror 325 are instead added.

The polarizing beam splitter 324 is so disposed that the pulsed laser light having a polarization plane perpendicular to the plane XZ is S-polarized light and enters the attenuator 130. The polarizing beam splitter 324 is coated with a film configured to reflect the S-polarized light at high reflectance and transmit the P-polarized light at high transmittance.

The high-reflectance mirror 325 is so disposed as to reflect the light having passed through the polarizing beam splitter 324 and cause the reflected light to enter the attenuator 330.

8.2 Operation

The pulsed laser light having a polarization plane perpendicular to the plane XZ is outputted from the laser apparatus 24. The pulsed laser light outputted from the laser apparatus 24 enters the retarder 255.

The retarder 255 is configured to rotate the polarization plane of the pulsed laser light by 2θ. The pulsed laser light having the rotated polarization plane is incident on the beam splitter 70p.

Part of the pulsed laser light having the component polarized in the direction perpendicular to the plane XZ is reflected by the beam splitter 70p of the OPS system 32, and the remainder of the pulsed laser light passes through the beam splitter 70p and is therefore stretched by the OPS system 32 in terms of pulse.

On the other hand, the pulsed laser light having the component polarized in the plane XZ passes through the beam splitter 70p at high transmittance and is not stretched in terms of pulse.

The pulsed laser light having passed through the OPS system 32 is incident on the polarizing beam splitter 324 of the radiation optical system 114. The component polarized in the direction perpendicular to the plane XZ and stretched by the OPS system 32 in terms of pulse is reflected off the polarizing beam splitter 324 at high reflectance and enters the illumination optical system 140 via the attenuator 130 and the high-reflectance mirrors 122 and 123.

The pulsed laser light having passed through the illumination optical system 140 is shaped into a rectangular linear beam having a homogenized intensity distribution and radiated as pulsed laser light for laser annealing onto the mask 148.

On the other hand, the component polarized in the plane XZ and has not been stretched by the OPS system 32 in terms of pulse passes through the polarizing beam splitter 324 at high transmittance and enters the illumination optical system 340 via the high-reflectance mirror 325, the attenuator 330, and the high-reflectance mirrors 322 and 323.

The pulsed laser light having passed through the illumination optical system 340 is shaped into a rectangular linear beam having a homogenized intensity distribution and radiated as pulsed laser light for the ridge planarization onto the mask 148.

The operation of radiating the pulsed laser light for laser annealing and the pulsed laser light for ridge planarization having passed through the mask 148 to the radiation receiving object 190 via the projection optical system 150 is the same as the operation described in the fourth embodiment.

The laser annealing controller 180 is configured to rotate the retarder 255 in such a way that a ratio Rab of pulse energy Ea of the pulsed laser light having passed through the retarder 255 and formed of the component polarized in the direction perpendicular to the plane XZ to pulse energy Eb of the pulsed laser light having passed through the retarder 255 and formed of the component polarized in the plane XZ satisfies Expression (13) below.

Rab=Ea/Eb=By·Bxa·Fa/(By·Bxr·Fr)=(Bxa·Fa)/(Bxr·Fr) (13)

8.3 Effects and Advantages

The fifth embodiment shown in FIG. 30 allows a single laser apparatus to perform the laser annealing and the ridge planarization, as compared with the third embodiment shown in FIG. 26.

The fifth embodiment shown in FIG. 30 improves the efficiency at which the pulsed laser light is used as compared with the third embodiment shown in FIG. 26 by rotating the optics axis of the retarder 255 to adjust the ratio between the pulsed laser light for laser annealing and the pulsed laser light for ridge planarization.

Further, even when the radiation conditions at the time of the laser annealing differ from those at the time of the ridge planarization, the efficiency at which the pulsed laser light is used can be optimized by adjusting the ratio between the pulsed laser light for laser annealing and the pulsed laser light for ridge planarization.

The combination of the laser apparatus 24 and the polarization bifurcating system 251 in the fifth embodiment is an example of the “laser system” in the present disclosure. The laser apparatus 24 is an example of the “fourth laser apparatus” in the present disclosure. The component polarized in the direction perpendicular to the plane XZ is an example of the “first polarized component” in the present disclosure. The component polarized in the plane XZ is an example of the “second polarized component” in the present disclosure.

8.4 Variations

[1] In the fifth embodiment, the polarization bifurcating system 251 is disposed between the laser annealing apparatus 100 and the laser apparatus 24, but not necessarily. For example, the polarization bifurcating system 251 may instead be disposed in the laser apparatus 24 or in the laser annealing apparatus 100.

[2] The attenuator 330 may not be disposed when the pulse energy of the pulsed laser light from the laser apparatus 24 falls within a controllable range.

[3] The ratio Rab of the pulse energy Ea of the pulsed laser light formed of the component polarized in the direction perpendicular to the plane XZ to the pulse energy Eb of the pulsed laser light formed of the component polarized in the plane XZ can be adjusted by adjusting the angle of rotation of the retarder 255, whereby at least one of the attenuators 130 and 330 can be omitted.

### 9. Sixth Embodiment

9.1 Configuration

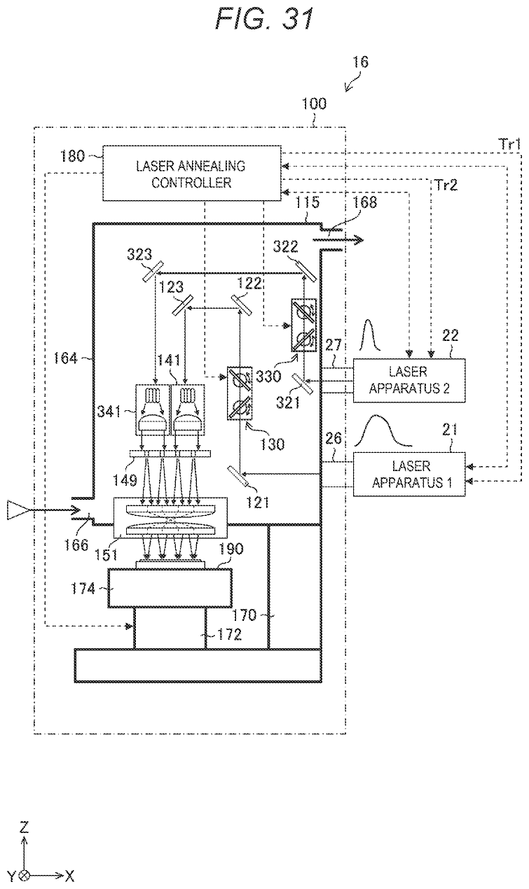

FIG. 31 schematically shows the configuration of a laser annealing system 16 according to a sixth embodiment. The sixth embodiment will be described with reference to a case where a projection optical system 151 is used to perform the laser annealing locally on an area that forms a TFT on the radiation receiving object 190. Differences in configuration between FIGS. 31 and 26 will be described.

A radiation optical system 115 of the laser annealing system 16 shown in FIG. 31 includes illumination optical systems 141 and 341 in place of the illumination optical systems 140 and 340 in FIG. 26. The laser annealing system 16 further includes a mask 149 and the projection optical system 151 in place of the mask 148 and the projection optical system 150 in FIG. 26.

The first pulsed laser light for laser annealing outputted from the first laser apparatus 21 enters the illumination optical system 141 via the high-reflectance mirror 121, the attenuator 130, and the high-reflectance mirrors 122 and 123.

The second pulsed laser light for ridge planarization outputted from the second laser apparatus 22 enters the illumination optical system 341 via the high-reflectance mirror 321, the attenuator 330, and the high-reflectance mirrors 322 and 323.

The illumination optical systems 141 and 341 are each an optical system for uniform illumination of a predetermined illumination receiving area on the mask 149 and are each so disposed that the mask 149 is illuminated in the form of Koehler illumination with a rectangular beam.

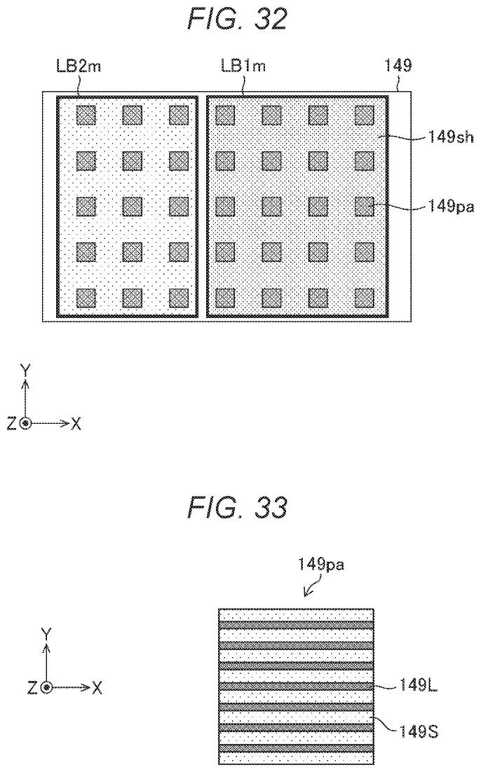

FIG. 32 shows an example of the mask 149 and a beam irradiated area of the mask 149. The mask 149 includes a plurality of pattern areas 149pa for forming a plurality of TFTs and a blocking area 149sh, as shown in FIG. 32. The plurality of pattern areas 149pa each have the same fine pattern configured to facilitate crystal growth (see FIG. 33).

FIG. 32 shows a uniformly illuminated area LB1m illuminated by the illumination optical system 141 and a uniformly illuminated area LB2m illuminated by the illumination optical system 341. The uniformly illuminated area LB1m is an area illuminated with a uniform beam for laser annealing. The uniformly illuminated area LB2m is an area illuminated with a uniform beam for ridge planarization.

The number of pattern areas 149pa in the X-axis direction in the uniformly illuminated area LB1m illuminated by the illumination optical system 141 is the number corresponding to the number of radiated pulses Na at the time of the laser annealing. The number of pattern areas 149pa in the X-axis direction in the uniformly illuminated area LB2m illuminated by the illumination optical system 341 is the number corresponding to the number of radiated pulses Nr at the time of the ridge planarization.

FIG. 32 shows a case where Na=4 and Nr=3 for ease of description. For example, in a case where Na=20 and Nr=10, the number of pattern areas 149pa arranged in the X-axis direction on the mask 149 may be 30; The number of pattern areas 149pa in the X-axis direction in the uniformly illuminated area LB1m illuminated by the illumination optical system 141 may be 20, and the number of pattern areas 149pa in the X-axis direction in the uniformly illuminated area LB2m illuminated by the illumination optical system 341 may be 10.

The number of pattern areas 149pa in the Y-axis direction in the uniformly illuminated area LB1m illuminated by the illumination optical system 141 is equal to the number in the uniformly illuminated area LB2m illuminated by the illumination optical system 341. FIG. 32 shows a case where the number of pattern areas 149pa in the Y-axis direction is five, but not necessarily, and the number may be a number that allows the fluence at the time of the laser annealing can be maintained.

FIG. 33 is an enlarged view showing an example of the fine pattern formed in each of the pattern areas 149pa. The fine pattern may be a line-and-space pattern formed of line sections 149L and space sections 149S alternately arranged, as shown in FIG. 33.

The fine pattern formed in each of the pattern areas 149pa may be a fine pattern configured to cause the laser annealing to form crystal nucleus according to the fine pattern followed by crystal growth. For example, the fine pattern may be a fine pattern formed of dots arranged at equal intervals in the X-axis and the Y-axis directions.

The projection optical system 150 shown in FIG. 31 is so disposed that an image of the fine pattern formed of the pattern areas 149pa of the mask 149 is brought into focus in a TFT formation area on the amorphous silicon on the radiation receiving object 190. In this case, the fine pattern formed on the pattern areas 149pa is projected onto the radiation receiving object 190.

9.2 Operation

The laser annealing controller 180 is configured to control the first laser apparatus 21 and the attenuator 130 in such a way that the fluence of the pulsed laser light for laser annealing is Fa. The laser annealing controller 180 is further configured to control the second laser apparatus 22 and the attenuator 330 in such a way that the fluence of the pulsed laser light for ridge planarization is Fr.

The laser annealing controller 180 is configured to calculate the X-axis-direction movement speed Vx of the XYZ-axis stage 172 in such a way that Expression (14) below is satisfied.

Vx=p·f (14)

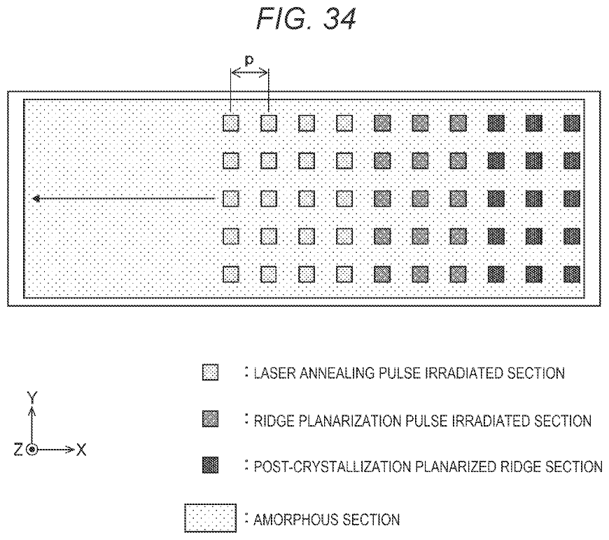

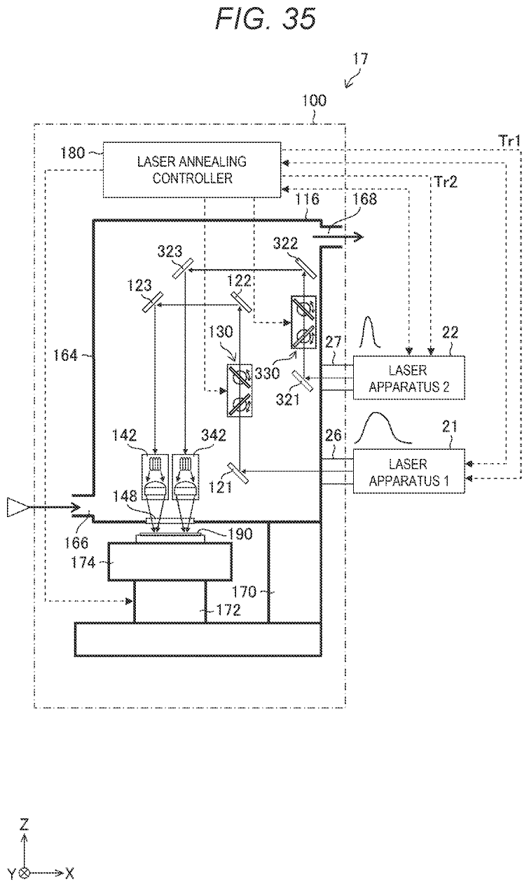

Symbol p represents the X-axis-direction interval between the TFT formation areas on the radiation receiving object 190 (see FIG. 34). Symbol f represents the repetitive frequency employed by the first laser apparatus 21 and the second laser apparatus 22. It is assumed in the description that the first laser apparatus 21 and the second laser apparatus 22 employ the same repetitive frequency f.

The laser annealing controller 180 is configured to set the X-axis-direction speed of the XYZ-axis stage 172 in such a way that the XYZ-axis stage 172 makes uniform speed linear motion at the speed of Vx.

FIG. 34 describes the operation of the laser annealing system 16 according to the sixth embodiment. The laser annealing controller 180 is configured to transmit the light emission trigger signals Tr1 and Tr2 to the first laser apparatus 21 and the second laser apparatus 22, respectively, with the light emission trigger signals Tr1 and Tr2 in synchronization with each other in such a way that the laser light is radiated when a pattern transferring image reaches each of the TFT formation areas on the surface of the radiation receiving object 190.

The pulsed laser light for laser annealing outputted from the first laser apparatus 21 and stretched in terms of pulse is radiated to each of the TFT formation areas on the surface of the radiation receiving object 190 under the radiation conditions including the fluence Fa, the number of radiated pulses Na, and the repetitive frequency f. As a result, the amorphous silicon in the TFT formation areas is laser-annealed, followed by crystal growth, so that the ridges are formed.

The TFT formation areas made of the crystallized polysilicon are each then irradiated with the pulsed laser light (pulsed laser light not stretched in terms of pulse) for ridge planarization outputted from the second laser apparatus 22 under the radiation conditions including the fluence Fr, the number of radiated pulses Nr, and the repetitive frequency f, so that the ridges are planarized.

In FIG. 34, 50 quadrangular areas arranged in an array formed of 5 rows and 10 columns show the TFT formation areas, in each of which a TFT is formed. From right to left in FIG. 34, a beam carrying a transferred pattern image for laser annealing and a beam carrying a transferred pattern image for ridge planarization are radiated.

The 5×4=20 quadrangular areas corresponding to 4 columns from left in FIG. 34 each represent a laser annealing pulse irradiated section. The laser annealing pulse irradiated sections are irradiated with the pulsed laser light for laser annealing, so that the amorphous silicon undergoes crystal growth to form the ridges. The quadrangular areas in the first column counted from left represent TFT formation areas where the pulse radiation for laser annealing has been performed once. The quadrangular areas in the second column counted from left represent TFT formation areas where the pulse radiation for laser annealing has been performed twice. The third column represents TFT formation areas where the pulse radiation has been performed three times, and the fourth column represents TFT formation areas where the pulse radiation has been performed four times.

When the number of radiated pulses Na at the time of the laser annealing is set at Na=4, the pulse radiation of the pulsed laser light for laser annealing is performed four times on one (same) TFT formation area.

The 5×3=15 quadrangular sections corresponding to three columns, the fifth, sixth, and seventh columns counted from left in FIG. 34 each represent a ridge planarization pulse irradiated section. The ridge planarization pulse irradiated sections are each an area crystallized by the preceding radiation of the pulses for laser annealing (number of radiated pulses Na) and are each irradiated with the pulsed laser light for ridge planarization, so that the ridges partially melt and are planarized.

The TFT formation areas in the fifth column are each an area where the pulse radiation of the pulsed laser light for ridge planarization has been performed once. The TFT formation areas in the sixth column are each a TFT formation area where the pulse radiation for ridge planarization has been performed twice. The TFT formation areas in the seventh column are each a TFT formation area where the pulse radiation for ridge planarization has been performed three times. When the number of radiated pulses Nr at the time of the ridge planarization is set at Nr=3, the pulse radiation of the pulsed laser light for ridge planarization is performed three times on one (same) TFT formation area.

The 5×3=15 TFT formation areas corresponding to 3 columns from right in FIG. 34 represent TFT formation areas where the pulse radiation for ridge planarization has been performed Nr times after the pulse radiation for laser annealing had been performed Na times.

In FIG. 34, the area other than the TFT formation areas is an amorphous section that is not irradiated with the laser light.

9.3 Effects and Advantages

The sixth embodiment provides the following effects and advantages as compared with those provided by the first embodiment described with reference to FIG. 17. That is, since the projection optical system 151 can reduce, transfer, and form an image of the mask pattern on each of the TFT formation areas on the radiation receiving object 190 to radiate the pulsed laser light for laser annealing and the pulsed laser light for ridge planarization, whereby the efficiency at which the pulsed laser light is used increases.

9.4 Variations

[1] The sixth embodiment shows the configuration using two laser apparatuses, the first laser apparatus 21, which is configured to output the pulsed laser light having a long pulse duration for laser annealing, and the second laser apparatus 22, which is configured to output the pulsed laser light having a short pulse duration for ridge planarization, but not necessarily. For example, in place of the first laser apparatus 21 and the second laser apparatus 22 in FIG. 31, the configuration in which the laser apparatus 23 and the bifurcating system 250 in FIG. 29 are disposed or the configuration in which the laser apparatus 24 and the polarization bifurcating system 251 are disposed, such as the configuration shown in FIG. 30, may be employed, and the pulsed laser light for laser annealing and the pulsed laser light for ridge planarization may be separately radiated.

[2] In the sixth embodiment, the single projection optical system 151, which is configured to project an image of the mask 149, is configured to transfer a plurality of pattern areas 149pa to the TFT formation areas and bring the images into focus thereon, but not necessarily. For example, the projection optical system may include a plurality of projection optical systems each configured to transfer one image to one pattern area and bring the image into focus thereon or may include a projection optical system for laser annealing and a projection optical system for ridge planarization.

### 10. Seventh Embodiment

10.1 Configuration

FIG. 35 schematically shows the configuration of a laser annealing system 17 according to a seventh embodiment. Differences in configuration between FIGS. 35 and 26 will be described. The form of the laser annealing system 17 shown in FIG. 35 differs from the form in FIG. 26 in that no projection optical system 150 is provided. A radiation optical system 116 of the laser annealing system 17 includes illumination optical systems 142 and 342 in place of the illumination optical systems 140 and 340 in FIG. 26. The mask 148 shown in FIG. 35 is disposed in the vicinity of the surface of the radiation receiving object 190. The distance between the mask 148 and the radiation receiving object 190 may, for example, range from 0.2 to 0.5 mm.

The illumination optical system 142 is configured to uniformly illuminate the surface of the radiation receiving object 190 with a linear beam via the mask 148. The linear beam radiated by the illumination optical system 142 to the radiation receiving object 190 is used to perform the laser annealing.

The illumination optical system 342 is configured to uniformly illuminate the surface of the radiation receiving object 190 with a linear beam via the mask 148. The linear beam radiated by the illumination optical system 342 to the radiation receiving object 190 is used to perform the ridge planarization.

10.2 Operation

The pulsed laser light for laser annealing and the pulsed laser light for ridge planarization pass through the mask 148 disposed in the vicinity of the radiation receiving object 190, and the pulsed laser light carrying a pattern close to the mask pattern is radiated onto the radiation receiving object 190.

10.3 Effects and Advantages

According to the seventh embodiment, the projection optical system can be omitted, whereby the system configuration can be simplified as compared with that in the third embodiment.

10.4 Variations

[1] The seventh embodiment shows the configuration using two laser apparatuses, the first laser apparatus 21, which is configured to output the pulsed laser light having a long pulse duration for laser annealing, and the second laser apparatus 22, which is configured to output the pulsed laser light having a short pulse duration for ridge planarization, but not necessarily. For example, in place of the first laser apparatus 21 and the second laser apparatus 22 in FIG. 35, the configuration in which the laser apparatus 23 and the bifurcating system 250 in FIG. 29 are disposed or the configuration in which the laser apparatus 24 and the polarization bifurcating system 251 are disposed, such as the configuration shown in FIG. 30, may be employed, and the pulsed laser light for laser annealing and the pulsed laser light for ridge planarization may be separately radiated.

### 11. Eighth Embodiment

11.1 Configuration

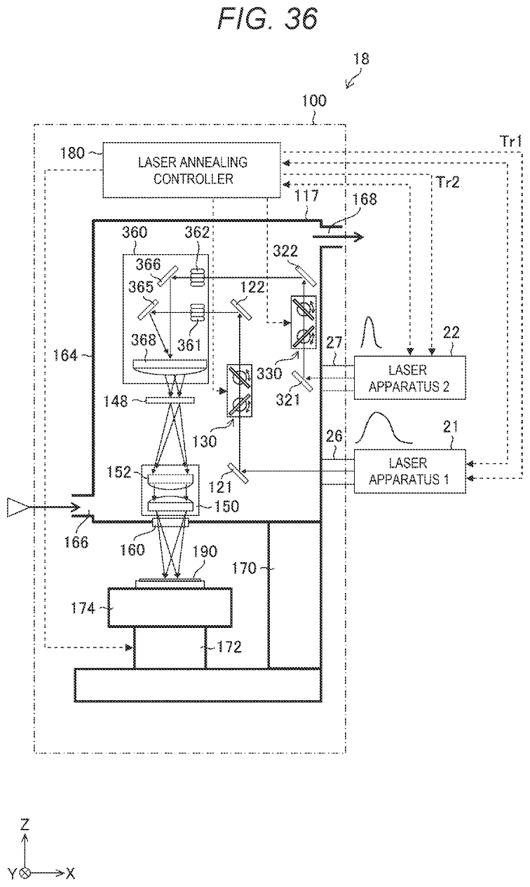

FIG. 36 schematically shows the configuration of a laser annealing system 18 according to an eighth embodiment. Differences in configuration between FIGS. 36 and 26 will be described.

The laser annealing system 18 shown in FIG. 36 includes a radiation optical system 117 in place of the radiation optical system 113 in FIG. 26. The radiation optical system 117 includes no high-reflectance mirror 123 or 323 or the illumination optical system 140 or 340 in FIG. 26 but instead includes an illumination optical system 360.

The illumination optical system 360 includes fly-eye lenses 361 and 362, high-reflectance mirrors 365 and 366, and a condenser lens 368.

The fly-eye lens 361 and the high-reflectance mirror 365 are disposed in an optical path of the pulsed laser light for laser annealing. The fly-eye lens 361 is so disposed that the pulsed laser light for laser annealing traveling from the high-reflectance mirror 122 enters the fly-eye lens 361.

The fly-eye lens 362 and the high-reflectance mirror 366 are disposed in an optical path of the pulsed laser light for ridge planarization. The fly-eye lens 362 is so disposed that the pulsed laser light for ridge planarization traveling from the high-reflectance mirror 322 enters the fly-eye lens 362. The high-reflectance mirror 366 is so disposed that the center axis of the pulsed laser light having passed through the fly-eye lens 362 enters the condenser lens 368 at right angles as shown in FIG. 36.

On the other hand, the high-reflectance mirror 365, which is disposed in the optical path of the pulsed laser light for laser annealing, is so disposed that the center axis of the pulsed laser light having passed through the fly-eye lens 361 enters the condenser lens 368 at an oblique angle as shown in FIG. 36.

11.2 Operation

Adjusting the angle of reflection at the high-reflectance mirror 365 allows adjustment of the position on the surface of the radiation receiving object 190 to which the linear beam LBa for laser annealing is radiated. That is, adjusting the angle of reflection at the high-reflectance mirror 365 allows adjustment of the relative positional relationship between the linear beam LBa for laser annealing and the linear beam LBr for ridge planarization on the surface of the radiation receiving object 190.

The angle of reflection at the high-reflectance mirror 365 is so adjusted that the linear beam LBr for ridge planarization is positioned in the vicinity of the linear beam LBa for laser annealing on the surface of the radiation receiving object 190.

11.3 Effects and Advantages Adjusting the angle of the high-reflectance mirror 365 allows the linear beam for ridge planarization to be positioned in the vicinity of and next to the linear beam for laser annealing. As a result, the distance over which the radiation receiving object 190 is moved in the X-axis direction can be shortened, whereby the throughput of the laser annealing apparatus is improved.

11.4 Variations

[1] In place of or in addition to the adjustment of the angle of the high-reflectance mirror 365, the angle of the high-reflectance mirror 366 may be adjusted to adjust the position of the linear beam for ridge planarization on the surface of the radiation receiving object 190.

[2] The high-reflectance mirror 365 may be provided with a tilting and rotating stage configured to tilt and rotate the high-reflectance mirror 365 around the axis Y, and the position of the linear beam for laser annealing may be controlled in accordance with the movement of the XYZ-axis stage 172 in the X-axis direction.

[3] A laser apparatus, a bifurcating system or a polarization bifurcating system may be disposed, as shown in FIGS. 29 and 30, and the pulsed laser light for laser annealing and the pulsed laser light for ridge planarization may be separately radiated.

### 12. Others

The technical items described in the embodiments and the variations described above may be combined with each other as appropriate to the extent that the combination is allowed.

An electronic device including a semiconductor element represented by a TFT can be manufactured by using a semiconductor thin film manufactured by the semiconductor crystalline thin film manufacturing method according to the present disclosure.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A method for manufacturing a semiconductor crystalline thin film, the method comprising:
radiating first pulsed laser light having a first pulse duration to an amorphous semiconductor to poly-crystallize the amorphous semiconductor; and
radiating second pulsed laser light having a second pulse duration shorter than the first pulse duration to an area of a semiconductor crystal having undergone the poly-crystallization to lower a height of ridges of the semiconductor crystal.

2. The method for manufacturing a semiconductor crystalline thin film according to claim 1,
wherein a relationship Fr<Fa is satisfied,
where Fa represents fluence of the first pulsed laser light, and Fr represents fluence of the second pulsed laser light.

3. The method for manufacturing a semiconductor crystalline thin film according to claim 1,
wherein a relationship Nr<Na is satisfied,
where Na represents the number of radiated pulses of the first pulsed laser light radiated to a single area of a radiation receiving object containing the amorphous semiconductor, and Nr represents the number of radiated pulses of the second pulsed laser light radiated to the single area.

4. The method for manufacturing a semiconductor crystalline thin film according to claim 1,
wherein the second pulse duration is shorter than or equal to 60% of the first pulse duration.

5. The method for manufacturing a semiconductor crystalline thin film according to claim 1,
wherein the radiation of the second pulsed laser light to an area on the radiation receiving object that is an area irradiated with the first pulsed laser light is started at least 200 nanoseconds after the first pulsed laser light is radiated to the irradiated area.

6. The method for manufacturing a semiconductor crystalline thin film according to claim 1,
wherein the amorphous semiconductor is amorphous silicon.

7. The method for manufacturing a semiconductor crystalline thin film according to claim 1,
further comprising forming an illumination pattern carried by the first pulsed laser light and the second pulsed laser light by using a mask having a predetermined mask pattern,
wherein the illumination pattern according to the mask pattern and carried by the first pulsed laser light is radiated to the amorphous semiconductor, and
the illumination pattern according to the mask pattern and carried by the second pulsed laser light is radiated to the area of the semiconductor crystal having undergone the poly-crystallization.

8. The method for manufacturing a semiconductor crystalline thin film according to claim 7,
wherein the mask pattern includes a line-and-space pattern in which a line section that serves as a blocking section and a space section that serves as a light transmitting section are alternately arranged.

9. A laser annealing system comprising:
a laser system configured to output first pulsed laser light having a first pulse duration and second pulsed laser light having a second pulse duration shorter than the first pulse duration; and
a laser annealing apparatus configured to radiate the first pulsed laser light and the second pulsed laser light to a radiation receiving object,
the laser annealing apparatus including
a radiation optical system configured to guide the first pulsed laser light and the second pulsed laser light to the radiation receiving object,
a movement mechanism configured to move relative to the radiation receiving object radiation positions to which the first pulsed laser light and the second pulsed laser light are radiated, and
a controller configured to control the laser system in such a way that the first pulsed laser light is radiated to the radiation receiving object and after the first pulsed laser light is radiated, the second pulsed laser light is radiated to an area of the radiation receiving object that is an area to which the first pulsed laser light is radiated.

10. The laser annealing system according to claim 9,
wherein the radiation receiving object irradiated with the first pulsed laser light is an amorphous semiconductor, and
the controller is configured to control the laser system and the movement mechanism in such a way that the first pulsed laser light is radiated to the amorphous semiconductor to poly-crystalize the amorphous semiconductor and the second pulsed laser light is radiated to an area of a semiconductor crystal having undergone the poly-crystallization to lower a height of ridges of the semiconductor crystal.

11. The laser annealing system according to claim 10,
wherein fluence and the first pulse duration of the first pulsed laser light are so set that the amorphous semiconductor is fully melted, and
fluence and the second pulse duration of the second pulsed laser light are so set that the ridges of the semiconductor crystal that are generated by the poly-crystallization is lowered.

12. The laser annealing system according to claim 9,
wherein the radiation optical system includes a mask having a predetermined mask pattern, and
illumination patterns according to the mask pattern and carried by the first pulsed laser light and the second pulsed laser light are radiated to the radiation receiving object.

13. The laser annealing system according to claim 12,
wherein the radiation optical system includes a transfer optical system configured to transfer the mask pattern of the mask onto the radiation receiving object and bring an image of the mask pattern into focus on the radiation receiving object.

14. The laser annealing system according to claim 13,
wherein the transfer optical system is a projection optical system configured to bring an image of the mask pattern into focus in each of a plurality of areas of the radiation receiving object in each of which a thin film transistor is formed.

15. The laser annealing system according to claim 9,
wherein the laser system includes
a laser oscillator configured to output pulsed laser light,
an optical pulse stretcher configured to stretch pulses of pulsed laser light outputted from the laser oscillator, and
an optical element switching unit configured to switch an optical element placed in an optical path so as to switch the optical path of the optical pulse stretcher, and
the controller is configured to control output of the first pulsed laser light and the second pulsed laser light by controlling the optical element switching unit to switch the optical element in the optical path.

16. The laser annealing system according to claim 9,
wherein the laser system includes
a laser oscillator configured to output pulsed laser light,
an optical pulse stretcher configured to stretch pulses of pulsed laser light outputted from the laser oscillator, and
a shutter disposed in a delaying optical path of the optical pulse stretcher, and
the controller is configured to control output of the first pulsed laser light and the second pulsed laser light by controlling opening and closing of the shutter.

17. The laser annealing system according to claim 9,
wherein the laser system includes
a first laser apparatus configured to output the first pulsed laser light, and
a second laser apparatus configured to output the second pulsed laser light.

18. The laser annealing system according to claim 17,
wherein the first laser apparatus includes
a laser oscillator configured to output pulsed laser light, and
an optical pulse stretcher configured to stretch pulses of pulsed laser light output from the laser oscillator.

19. The laser annealing system according to claim 9,
wherein the laser system includes
a third laser apparatus configured to output pulsed laser light,
an optical pulse stretcher configured to stretch pulses of the pulsed laser light outputted from the third laser apparatus, and
a beam splitter disposed in an optical path between the third laser apparatus and the optical pulse stretcher,
the first pulsed laser light, which is laser light stretched by the optical pulse stretcher in terms of pulse, is outputted, and
the second pulsed laser light, which is laser light bifurcated by the beam splitter, is outputted.

20. The laser annealing system according to claim 9,
wherein the laser system includes
a fourth laser apparatus configured to output pulsed laser light,
an optical pulse stretcher configured to stretch pulses of the pulsed laser light outputted from the fourth laser apparatus, and
a retarder disposed in an optical path between the fourth laser apparatus and the optical pulse stretcher,
the first pulsed laser light, which is laser light formed of a first polarized component stretched by the optical pulse stretcher in terms of pulse, is outputted, and
the second pulsed laser light, which is laser light formed of a second polarized component that is not stretched by the optical pulse stretcher in terms of pulse, is outputted.
